(19) United States
(12) Patent Application Publication
(10) Pub. No.: US 2010/0078071 A1
(43) Pub. Date: Apr. 1, 2010

(54) PHOTOELECTRIC CONVERSION DEVICE AND METHOD FOR MANUFACTURING THE SAME

(75) Inventors: Hidekazu Miyairi, Isehara (JP); Takuya Hirohashi, Atsugi (JP); Akihisa Shimomura, Atsugi (JP)

Correspondence Address: FISH & RICHARDSON P.C., P.O. BOX 1022, MINNEAPOLIS, MN, 55440-1022, US

(73) Assignee: Semiconductor Energy Laboratory Co., Ltd., Atsugi-shi (JP)

(21) Appl. No.: 12/566,015

(22) Filed: Sep. 24, 2009

(30) Foreign Application Priority Data
Sep. 26, 2008 (JP) 2008-248422

(51) Int. Cl. H01L 31/0368; H01L 31/18

(52) U.S. Cl. 136/258; 438/97; 257/53; 438/73; 257/E31.002

(57) ABSTRACT

A photoelectric conversion device includes one or more unit cells between a first electrode and a second electrode, in which a semiconductor junction is formed by sequentially stacking: a first impurity semiconductor layer of one conductivity type; an intrinsic non-single-crystal semiconductor layer including an NH group or an NH₂ group; and a second impurity semiconductor layer of opposite conductivity type to the first impurity semiconductor layer. In the non-single-crystal semiconductor layer of a unit cell on a light incident side, the nitrogen concentration measured by secondary ion mass spectrometry is 5×10¹⁸/cm³ or more and 5×10²⁰/cm³ or less and oxygen and carbon concentrations measured by secondary ion mass spectrometry are less than 5×10¹⁸/cm³.

### BACKGROUND OF THE INVENTION

1. Field of the Invention

The present invention relates to a photoelectric conversion device and a method for manufacturing the same.

2. Description of the Related Art

In order to take measures against global environmental issues including global warming, the market for photoelectric conversion devices typified by solar cells has expanded. Bulk photoelectric conversion devices of crystal silicon which achieve high photoelectric conversion efficiency have already been put into practical use. For bulk photoelectric conversion devices of crystal silicon, bulk silicon substrates such as single crystal silicon substrates or polycrystalline silicon substrates are used. However, most part of a bulk silicon substrate serves as a support which does not contribute to photoelectric conversion. Further, in recent years, silicon has been in very short supply for recovery of the semiconductor market and for rapid growth of the solar cell market. From such aspects, bulk photoelectric conversion devices of crystal silicon have difficulty in resource saving and cost reduction.

On the other hand, in thin film type photoelectric conversion devices of non-single-crystal silicon which use thin amorphous silicon films, thin microcrystalline silicon films, and the like, thin silicon films exhibiting a photoelectric conversion function are formed over support substrates by using a variety of chemical or physical vapor deposition methods. Therefore, it is said that thin film type photoelectric conversion devices of non-single-crystal silicon can achieve resource saving and cost reduction as compared to the bulk photoelectric conversion devices.

However, non-single-crystal silicon thin films such as thin amorphous silicon films and thin microcrystalline silicon films have defects serving as carrier traps, such as dangling bonds and crystal grain boundaries. Therefore, it is difficult to obtain sufficient photoelectric conversion efficiency, and thus, bulk photoelectric conversion devices of crystal silicon have got a larger share in the solar cell market.

Further, as a factor of low photoelectric conversion efficiency of a thin non-single-crystal silicon film, an impurity included in a thin film is given. A thin non-single-crystal silicon film is typically formed by a CVD method or the like, but impurities such as oxygen and carbon are introduced during formation of a film or the like. Therefore, a thin non-single-crystal silicon film including oxygen, carbon, and the like is formed.

Therefore, an attempt to improve performance of a photoelectric conversion device by controlling the concentration of specific residual impurity atoms included in a thin non-single-crystal silicon film to be within an appropriate concentration range is proposed (for example, Patent Document 1: Japanese Published Patent Application No. 2000-58889).

In Patent Document 1, the oxygen concentration and the carbon concentration are mentioned, but the nitrogen concentration is not discussed. Further, in Patent Document 1, nitrogen is regarded as a residual impurity like oxygen and carbon and thus it is thought that the nitrogen concentration be preferably as low as possible.

### SUMMARY OF THE INVENTION

In view of the above problems, it is an object of one embodiment of the present invention to form a non-single-crystal semiconductor layer in which defects are reduced, as a semiconductor layer forming a semiconductor junction of a photoelectric conversion device. It is another object of an embodiment of the present invention to improve photoelectric conversion efficiency of a photoelectric conversion device formed using a non-single-crystal semiconductor layer.

Another embodiment of the present invention is to provide a photoelectric conversion device having, as a semiconductor layer forming the photoelectric conversion device, a non-single-crystal semiconductor layer in which nitrogen concentration is within a predetermined range and oxygen concentration and carbon concentration are low. In specific, a non-single-crystal semiconductor layer in which the peak concentration of nitrogen, which is measured by secondary ion mass spectrometry, is 5×10¹⁸/cm³ or more and 5×10²⁰/cm³ or less, preferably 1×10¹⁹/cm³ or more and 5×10²⁰/cm³ or less and the peak concentrations of oxygen and carbon, which are measured by secondary ion mass spectrometry, are less than 5×10¹⁸/cm³, preferably less than 1×10¹⁸/cm³ is formed in a unit cell including a semiconductor junction.

Note that the non-single-crystal semiconductor layer preferably contains an NH group.

Another embodiment of the present invention is a photoelectric conversion device including one or more unit cells between a first electrode and a second electrode, in which a semiconductor junction is formed by sequentially stacking a first impurity semiconductor layer of one conductivity type; a non-single-crystal semiconductor layer; and a second impurity semiconductor layer of opposite conductivity type to the first impurity semiconductor layer. In the non-single-crystal semiconductor layer of a unit cell on a light incident side, the peak concentration of nitrogen, which is measured by secondary ion mass spectrometry, is 5×10¹⁸/cm³ or more and 5×10²⁰/cm³ or less and peak concentrations of oxygen and carbon, which are measured by secondary ion mass spectrometry, are less than 5×10¹⁸/cm³.

In the above structure, in the non-single-crystal semiconductor layer, the peak concentration of nitrogen, which is measured by secondary ion mass spectrometry, is preferably 1×10¹⁹/cm³ or more and 5×10²⁰/cm³ or less.

In the above structure, the non-single-crystal semiconductor layer preferably includes an NH group.

Further, a structure including an amorphous semiconductor layer between the first impurity semiconductor layer and the non-single-crystal semiconductor layer may be used.

Another embodiment of the present invention is a method for manufacturing a photoelectric conversion device comprising the steps of: over a substrate, forming a first electrode; over the first electrode, forming one or more unit cells in which a semiconductor junction is formed by sequentially stacking a first impurity semiconductor layer of one conductivity type, a non-single-crystal semiconductor layer having a peak concentration of nitrogen, which is measured by secondary ion mass spectrometry, of 5×10¹⁸/cm³ or more and 5×10²⁰/cm³ or less and peak concentrations of oxygen and carbon, which are measured by secondary ion mass spectrometry, of less than 5×10¹⁸/cm³, and a second impurity semiconductor layer of opposite conductivity type to the first impurity semiconductor layer; and forming a second electrode over the unit cell.

In the above structure, the non-single-crystal semiconductor layer is preferably formed by introducing a semiconductor source gas, a dilution gas, and a gas including nitrogen into a treatment chamber which is subjected to vacuum exhaust to a degree of vacuum of 1×10⁻⁸ Pa or less, preferably 1×10⁻⁵ Pa or less and by producing plasma. Further, a gas including ammonia, chloroamine, fluoroamine, or the like, or nitrogen is preferably used as the gas including nitrogen.

In this specification, a nitrogen concentration, an oxygen concentration, and a carbon concentration are peak concentrations which are measured by secondary ion mass spectrometry (SIMS).

The term “non-single-crystal semiconductor” in this specification includes a substantially intrinsic semiconductor in its category, and specifically, refers to a non-single-crystal semiconductor which has an impurity imparting p-type conductivity (typically boron) or n-type conductivity (typically phosphorus, and note that nitrogen is not included in an impurity imparting n-type conductivity here) at a concentration of 1×10²⁰ cm⁻³ or less and which has photoconductivity of 100 times or more the dark conductivity. Note that there is a case where a non-single-crystal semiconductor has weak n-type conductivity when an impurity element for controlling valence electrons is not added intentionally; therefore, an impurity element imparting p-type conductivity (typically boron) may be added concurrently with film formation or after film formation. In such a case, the concentration of a p-type impurity included in a non-single-crystal semiconductor is approximately 1×10¹⁴/cm⁻³ to 6×10¹⁶/cm⁻³.

The term “photoelectric conversion layer” in this specification includes in its category a semiconductor layer by which a photoelectric (internal photoelectric) effect is achieved and moreover an impurity semiconductor layer which is joined to form an internal electric field or a semiconductor junction. That is to say, the photoelectric conversion layer in this specification refers to a semiconductor layer having a junction typified by a p-i-n junction or the like.

The term “p-i-n junction” in this specification includes a junction in which a p-type semiconductor layer, an i-type semiconductor layer, and an n-type semiconductor layer are stacked in this order from the light incidence side and a junction in which an n-type semiconductor layer, an i-type semiconductor layer, and a p-type semiconductor layer are stacked in this order from the light incidence side.

Note that in this specification, a numeral such as “first”, “second”, or “third” which are included in a term is given for convenience in order to distinguish elements, and does not limit the number, the arrangement, and the order of the steps.

According to one embodiment of the present invention, a photoelectric conversion device having, as a photoelectric conversion layer, a non-single-crystal semiconductor layer in which defects are reduced can be provided. Further, photoelectric conversion efficiency of a photoelectric conversion device having a non-single-crystal semiconductor layer can be improved.

### BRIEF DESCRIPTION OF DRAWINGS

FIG. 1 is a schematic cross-sectional view illustrating a photoelectric conversion device of one embodiment of the present invention.

FIG. 2 is a schematic cross-sectional view illustrating a plasma CVD apparatus which is applicable to manufacture of a photoelectric conversion device of one embodiment of the present invention.

FIG. 3 is a schematic plan view illustrating a multi-chamber plasma CVD apparatus which is applicable to manufacture of a photoelectric conversion device of one embodiment of the present invention.

FIGS. 4A and 4B illustrate Model 1 and Model 2 which illustrate a non-single-crystal semiconductor layer, respectively.

FIGS. 5A and 5B illustrate the shape of a wave function of Model 1 and the shape of a wave function of Model 2, respectively.

FIG. 6 is a schematic cross-sectional view illustrating a photoelectric conversion device of another embodiment of the present invention.

FIG. 7 is a schematic cross-sectional view illustrating a photoelectric conversion device of another embodiment of the present invention.

FIGS. 8A to 8C are cross-sectional views illustrating a method for manufacturing a photoelectric conversion device module of one embodiment of the present invention.

FIG. 9 is a cross-sectional view illustrating a method for manufacturing a photoelectric conversion device module of one embodiment of the present invention.

FIG. 10 is a drawing illustrating a non-single-crystal semiconductor layer of one embodiment of the present invention.

FIGS. 11A to 11C are drawings illustrating a non-single-crystal semiconductor layer of one embodiment of the present invention.

FIG. 12 is a graph illustrating a non-single-crystal semiconductor layer of one embodiment of the present invention.

FIGS. 13A to 13D are drawings illustrating a non-single-crystal semiconductor layer of one embodiment of the present invention.

FIGS. 14A and 14B are drawings illustrating a non-single-crystal semiconductor layer of one embodiment of the present invention.

FIG. 15 is a graph illustrating a non-single-crystal semiconductor layer of one embodiment of the present invention.

### DETAILED DESCRIPTION OF THE INVENTION

Embodiments of the present invention will be explained with reference to the drawings. However, the present invention is not limited to the following description, and it is easily understood by those skilled in the art that modes and details can be variously changed without departing from the scope and the spirit of the present invention. Therefore, the present invention should not be interpreted as being limited to the description of the embodiments given below. Note that, in structures of the present invention described below, the reference numerals indicating the same portions are used in common in the drawings.

### Embodiment 1

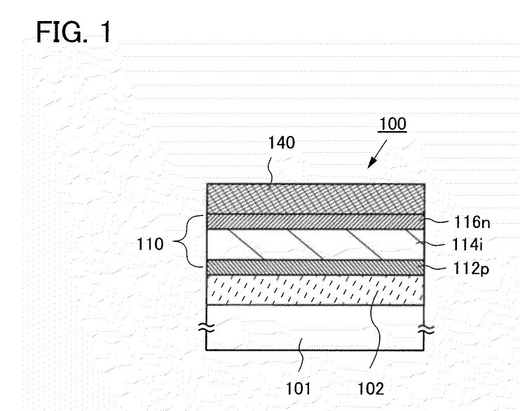

FIG. 1 illustrates an example of a schematic cross-sectional view of a photoelectric conversion device 100 of this embodiment.

The photoelectric conversion device 100 illustrated in FIG. 1 has a structure in which a unit cell 110 is interposed between a first electrode 102 and a second electrode 140 which are provided over a substrate 101. In the unit cell 110, a non-single-crystal semiconductor layer 114i is provided between a first impurity semiconductor layer 112p and a second impurity semiconductor layer 116n, and the unit cell 110 includes at least one semiconductor junction. As the semiconductor junction, a p-i-n junction is typically given.

The non-single-crystal semiconductor layer 114i is a semiconductor layer in which the nitrogen concentration, the oxygen concentration, and the carbon concentration are controlled. In the non-single-crystal semiconductor layer 114i, the nitrogen concentration is within a predetermined range and the oxygen concentration and the carbon concentration are kept as low as possible. The nitrogen concentration range in the non-single-crystal semiconductor layer 114i is set so that semiconductivity is kept and photoelectric conversion efficiency is improved. Further, it is preferable that an NH group be contained in the non-single-crystal semiconductor layer 114i.

In specific, in the non-single-crystal semiconductor layer 114i, the peak concentration of nitrogen, which is measured by secondary ion mass spectrometry, is 5×10¹⁸/cm³ or more and 5×10²⁰/cm³ or less, preferably 1×10¹⁹/cm³ or more and 5×10²⁰/cm³ or less, and the peak concentrations of oxygen and carbon, which are measured by secondary ion mass spectrometry, are less than 5×10¹⁸/cm³, preferably less than 1×10¹⁸/cm³. The concentration is within the above-described range for the following reasons. If the nitrogen concentration in the non-single-crystal semiconductor layer 114i is too high, low semiconductivity and a high insulating property are obtained, and thus, a function of photoelectric conversion cannot be provided. On the contrary, if the nitrogen concentration is too low, a non-single-crystal semiconductor layer which is similar to a conventional one is obtained.

Note that as the non-single-crystal semiconductor layer 114i, a semiconductor layer other than a single crystal semiconductor layer is used. Typically, the non-single-crystal semiconductor layer 114i is formed using non-single-crystal silicon.

Either the first impurity semiconductor layer 112p or the second impurity semiconductor layer 116n is formed using a p-type semiconductor layer, and the other is formed using an n-type semiconductor layer. In this embodiment, a structure in which light is incident on the substrate 101 side is described; therefore, a p-type semiconductor layer is formed as the first impurity semiconductor layer 112p and an n-type semiconductor layer is formed as the second impurity semiconductor layer 116n.

Note that the first impurity semiconductor layer 112p and the second impurity semiconductor layer 116n are formed using a microcrystalline semiconductor (typically, microcrystalline silicon or the like) or an amorphous semiconductor (typically, amorphous silicon, amorphous silicon carbide, or the like).

As the substrate 101, a substrate with an insulating surface or an insulating substrate is used. In this embodiment, light is incident from the substrate 101 side; therefore, a light-transmitting substrate is used. As the substrate 101, for example, various commercially available glass plates such as soda-lime glass, opaque glass, lead glass, strengthened glass, and ceramic glass; a non-alkali glass substrate such as an aluminosilicate glass substrate or a barium borosilicate glass substrate; a quartz substrate; and the like are given.

In this embodiment, light is incident from the substrate 101 side; therefore, as the first electrode 102, a light-transmitting electrode is formed. In specific, a light-transmitting electrode is formed using a light-transmitting conductive material such as indium oxide, indium tin oxide (ITO) alloy, or zinc oxide, or a light-transmitting conductive high molecular material. As the second electrode 140, a reflective electrode is formed using a conductive material such as aluminum, silver, titanium, tantalum, or copper.

Next, a photoelectric conversion device shown in FIG. 1 is described in detail with respect to specific components thereof, a material thereof which can be used for each component, and a manufacturing method thereof.

The first electrode 102 is formed over the substrate 101.

There is no particular limitation on the substrate 101 as long as the substrate 101 can withstand a manufacturing process of the photoelectric conversion device of one embodiment of the present invention. A substrate with an insulating surface or an insulating substrate can be used. A glass substrate is preferably used because a large substrate can be used and cost can be reduced. For example, large substrates which are distributed as glass substrates for liquid crystal displays having a size of 300 mm×400 mm called the first generation, 550 mm×650 mm called the third generation, 730 mm×920 mm called the fourth generation, 1000 mm×1200 mm called the fifth generation, 2450 mm×1850 mm called the sixth generation, 1870 mm×2200 mm called the seventh generation, and 2000 mm×2400 mm called the eighth generation, or the like can be used for the substrate 101.

As the first electrode 102, a light-transmitting electrode is formed using a light-transmitting conductive material such as indium oxide, indium tin oxide (ITO) alloy, or zinc oxide by a sputtering method or the like. Further, the first electrode 102 may be formed using a light-transmitting conductive high molecular material (also referred to as conductive polymer). As the conductive high molecular material, π electron conjugated conductive high molecule can be used. For example, polyaniline and/or a derivative thereof, polypyrrole and/or a derivative thereof, polythiophene and/or a derivative thereof, and a copolymer of two or more kinds of those materials can be given.

Over the first electrode 102, the first impurity semiconductor layer 112p, the non-single-crystal semiconductor layer 114i, and the second impurity semiconductor layer 116n are formed.

The first impurity semiconductor layer 112p, the non-single-crystal semiconductor layer 114i, and the second impurity semiconductor layer 116n are formed using a semiconductor source gas and a dilution gas as a reaction gas by a chemical vapor deposition (CVD) method, typically by a plasma CVD method. As the semiconductor source gas, a silicon hydride typified by silane or disilane, a silicon chloride such as SiH₂Cl₂, SiHCl₃, or SiCl₄, or a silicon fluoride such as SiF₄ can be used. As the dilution gas, hydrogen is typically given. As well as hydrogen, one or more kinds of rare gas elements selected from helium, argon, krypton, and neon can be used as the dilution gas. Further, as the dilution gas, plural kinds of gases (e.g., hydrogen and argon) can be used in combination.

For example, the first impurity semiconductor layer 112p, the non-single-crystal semiconductor layer 114i, and the second impurity semiconductor layer 116n can be formed using the reaction gas with a plasma CVD apparatus by applying a high-frequency power with a frequency of from 1 MHz to 200 MHz. Instead of applying the high-frequency power, a microwave power with a frequency of from 1 GHz to 5 GHz, typically 2.45 GHz may be applied. For example, the first impurity semiconductor layer 112p, the non-single-crystal semiconductor layer 114i, and the second impurity semiconductor layer 116n can be formed using glow discharge plasma in a treatment chamber of a plasma CVD apparatus with use of a mixture of silicon hydride (typically silane) and hydrogen. The glow discharge plasma is produced by applying high-frequency power with a frequency of from 1 MHz to 20 MHz, typically 13.56 MHz, or high-frequency power with a frequency of 20 MHz to about 120 MHz in the VHF band, typically 27.12 MHz or 60 MHz. The substrate is heated at from 100° C. to 300° C., preferably at from 120° C. to 220° C.

As the non-single-crystl semiconductor layer 114i, a semiconductor layer in which the nitrogen concentration is within a predetermined range and the concentrations of oxygen and carbon which are contained as impurities are as low as possible is formed. In specific, as the non-single-crystal semiconductor layer 114i, a semiconductor layer in which the nitrogen concentration is 5×10¹⁸/cm³ or more and 5×10²⁰/cm³ or less, preferably 1×10¹⁹/cm³ or more and 5×10²⁰/cm³ or less, and the oxygen concentration and the carbon concentration are less than 5×10¹⁸/cm³, preferably less than 1×10¹⁸/cm³, is formed. Such a non-single-crystal semiconductor layer 114i can be formed in the following manner: a reaction gas is introduced into a treatment chamber in which the oxygen concentration and the carbon concentration are as low as possible and predetermined pressure is kept, and glow discharge plasma is produced, whereby nitrogen is contained in formation of a film (the non-single-crystal semiconductor layer 114i) or the like. It is preferable that nitrogen be contained in the non-single-crystal semiconductor layer 114i by including a nitrogen element and a hydrogen element, or an NH group in an atmosphere of a treatment chamber in formation of the non-single-crystal semiconductor layer 114i. In addition, it is preferable that the oxygen concentration and the carbon concentration of the reaction gas used for formation of the non-single-crystal semiconductor layer 114i be as low as possible. In specific, as the reaction gas used for forming the non-single-crystal semiconductor layer 114i, a gas including nitrogen of which the flow rate and the concentration are controlled so that the nitrogen concentration in the film is 5×10¹⁸/cm³ or more and 5×10²⁰/cm³ or less, preferably 1×10¹⁹/cm³ or more and 5×10²⁰/cm³ or less is used. Further, the oxygen concentration and the carbon concentration in a treatment chamber and the oxygen concentration and the carbon concentration of the reaction gas (purity of the reaction gas) are controlled so that the oxygen concentration and the carbon concentration in the film (the non-single-crystal semiconductor layer 114i) are less than 5×10¹⁸/cm³, preferably less than 1×10¹⁸/cm³.

Further, in order to make the oxygen concentration and the carbon concentration in the non-single-crystal semiconductor layer 114i as low as possible, the non-single-crystal semiconductor layer 114i is preferably formed in an ultra high vacuum (UHV) treatment chamber. In specific, the non-single-crystal semiconductor layer 114i is preferably formed in a treatment chamber in which the degree of vacuum can reach 1×10⁻⁸ Pa or less, preferably 1×10⁻⁵ Pa or less.

Here, as one of means for forming a semiconductor layer as the non-single-crystal semiconductor layer 114i such that the concentrations of oxygen and carbon which are contained as impurities are as low as possible and the nitrogen concentration is within a predetermined range, the following can be given.

As one means, the non-single-crystal semiconductor layer 114i is formed under the condition where the oxygen concentration and the carbon concentration of a reaction gas to be introduced into a treatment chamber are made low and the nitrogen concentration is made high. Further, as the reaction gas, a gas including nitrogen (typically, a gas including ammonia, chloroamine, fluoroamine, or the like; nitrogen; or the like) may be used.

As another means, an inner wall of a treatment chamber used for formation of the non-single-crystal semiconductor layer 114i is covered with a layer containing nitrogen at high concentration. As the layer containing nitrogen at high concentration, a silicon nitride layer is formed, for example. Further, as a reaction gas for forming the layer containing nitrogen at high concentration, a gas including nitrogen (typically, a gas including ammonia, chloroamine, fluoroamine, or the like; nitrogen; or the like) may be used.

As another means, after the non-single-crystal semiconductor layer 114i is formed under the condition where the oxygen concentration and the carbon concentration of a reaction gas to be introduced into a treatment chamber are kept low, nitrogen is added to the non-single-crystal semiconductor layer 114i. For example, after the non-single-crystal semiconductor layer 114i is formed, a gas including nitrogen (typically, a gas including ammonia, chloroamine, fluoroamine, or the like; nitrogen; or the like) is introduced into a treatment chamber and plasma is produced, whereby nitrogen is added to the non-single-crystal semiconductor layer 114i.

Note that as means for forming the non-single-crystal semiconductor layer 114i, one of the above means may be selected or two or more means may be combined.

A doping gas including an impurity imparting one conductivity type is mixed into a reaction gas including a semiconductor source gas and a dilution gas, so that an impurity semiconductor layer of one conductivity type is formed as the first impurity semiconductor layer 112p. In this embodiment, a doping gas including an impurity imparting p-type conductivity is mixed, so that a p-type semiconductor layer is formed. As the impurity imparting p-type conductivity, boron or aluminum which is an element belonging to Group 13 in the periodic table, or the like is typically given. For example, a doping gas such as diborane is mixed into a reaction gas, whereby a p-type semiconductor layer can be formed.

As the second impurity semiconductor layer 116n, an impurity semiconductor layer of conductivity type opposite to the first impurity semiconductor layer 112p is formed. In this embodiment, a doping gas including an impurity imparting n-type conductivity is mixed into a reaction gas, so that an n-type semiconductor layer is formed. As the impurity imparting n-type conductivity, typically, phosphorus, arsenic, or antimony which is an element belonging to Group 15 in the periodic table, or the like is typically given. For example, a doping gas such as phosphine is mixed into a reaction gas, whereby an n-type semiconductor layer can be formed.

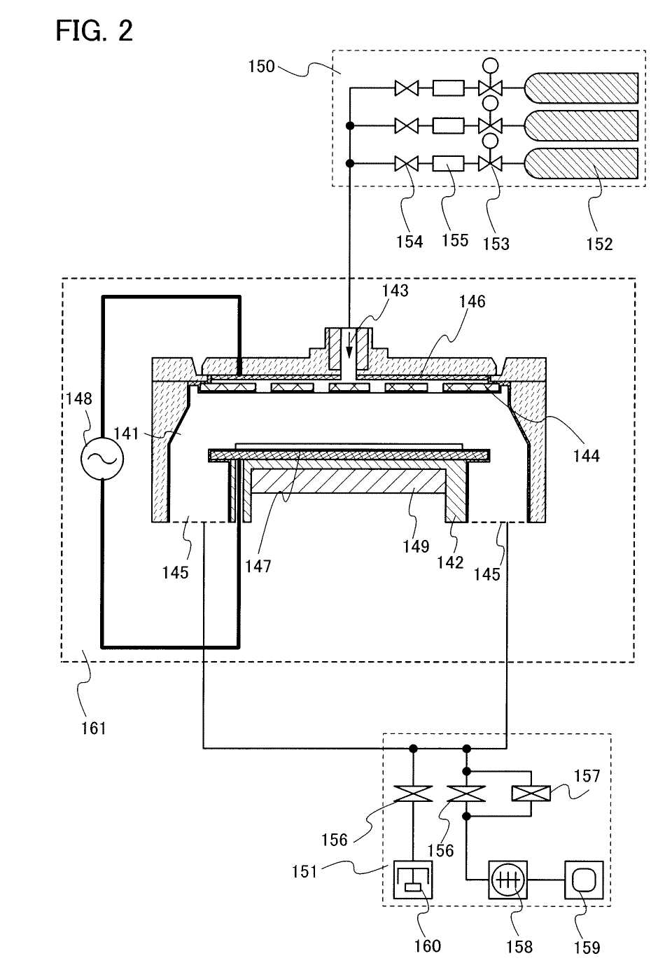

Here, FIG. 2 is a schematic view of a CVD apparatus which can be used for formation of the first impurity semiconductor layer 112p, the non-single-crystal semiconductor layer 114i, and the second impurity semiconductor layer 116n.

A plasma CVD apparatus 161 illustrated in FIG. 2 is connected to a gas supply means 150 and an exhaust means 151.

The plasma CVD apparatus 161 includes a treatment chamber 141, a stage 142, a gas supply portion 143, a shower plate 144, an exhaust port 145, an upper electrode 146, a lower electrode 147, an alternate-current power source 148, and a temperature controller 149.

The treatment chamber 141 is formed using a material having rigidity and the inside thereof can be subjected to vacuum exhaust (preferably ultra-high vacuum exhaust). The treatment chamber 141 is provided with the upper electrode 146 and the lower electrode 147. Note that in FIG. 2, a structure of a capacitive coupling type (a parallel plate type) is illustrated; however, another structure such as a structure of an inductive coupling type can be used, as long as plasma can be produced in the treatment chamber 141 by applying two or more different high-frequency powers.

Here, in order to form the non-single-crystal semiconductor layer 114i of this embodiment, it is preferable to provide an environment in which the oxygen concentration and the carbon concentration in the treatment chamber 141 are as low as possible. In specific, as the treatment chamber 141, an ultra high vacuum treatment chamber in which the degree of vacuum can reach 1×10⁻⁸ Pa or less, preferably 1×10⁻⁵ Pa or less is provided. After the treatment chamber 141 is subjected to vacuum exhaust to a degree of vacuum of 1×10⁻⁸ Pa or less, preferably 1×10⁻⁵ Pa or less, a reaction gas is introduced to form the non-single-crystal semiconductor layer 114i, whereby the concentrations of oxygen and carbon which are introduced in formation of the non-single-crystal semiconductor layer 114i can be low.

When treatment is performed with the plasma CVD apparatus 161 illustrated in FIG. 2, a given reaction gas is supplied from the gas supply portion 143. The supplied reaction gas is introduced into the treatment chamber 141 through the shower plate 144. High frequency power is applied by the alternate-current power source 148 connected to the upper electrode 146 and the lower electrode 147 to excite the reaction gas in the treatment chamber 141, thereby producing plasma. Further, the reaction gas in the process chamber 141 is exhausted through the exhaust port 145 that is connected to a vacuum pump. Further, with the use of the temperature controller 149, plasma treatment can be performed while an object is being heated.

The gas supply means 150 includes a cylinder 152 which is filled with a reaction gas, a pressure adjusting valve 153, a stop valve 154, a mass flow controller 155, and the like. The treatment chamber 141 includes the shower plate 144 which is processed in a plate-like shape and provided with a plurality of pores, between the upper electrode 146 and the object. An inner portion of the upper electrode 146 has a hollow structure. A reaction gas supplied to the upper electrode 146 is supplied to the treatment chamber 141 from these pores of the shower plate 144 through the inner portion of the upper electrode 146.

The exhaust means 151 which is connected to the treatment chamber 141 has a function of vacuum exhaust and a function of controlling the pressure in the treatment chamber 141 to be maintained at a predetermined level when a reaction gas is made to flow. The exhaust means 151 includes in its structure butterfly valves 156, a conductance valve 157, a turbo molecular pump 158, a dry pump 159, and the like. In the case of arranging the butterfly valve 156 and the conductance valve 157 in parallel, the butterfly valve 156 is closed and the conductance valve 157 is operated, so that the exhaust velocity of the reaction gas is controlled and thus the pressure in the treatment chamber 141 can be kept within a predetermined range. Moreover, the butterfly valve 156 having higher conductance is opened, so that high-vacuum exhaust can be performed.

In the case of subjecting the treatment chamber 141 to ultra-high vacuum exhaust, a cryopump 160 is preferably used together. Alternatively, when exhaust is performed to ultra-high vacuum as ultimate degree of vacuum, the inner wall of the treatment chamber 141 may be polished into a mirror surface, and a heater for baking may be provided in order to reduce gas emission from the inner wall.

Note that by precoating treatment performed so that a film is formed covering the entire inner wall of the reaction chamber 141, it is possible to prevent an impurity element attached to or included in the inner wall of the reaction chamber from mixing into a film (for example, the non-single-crystal semiconductor layer 114i) or the like. For example, in the case of forming a non-single-crystal silicon layer as the non-single-crystal semiconductor layer 114i, a film containing silicon as its main component (for example, amorphous silicon) may be formed as precoating treatment. Note that it is preferable that oxygen and carbon be not contained in the film formed by precoating treatment.

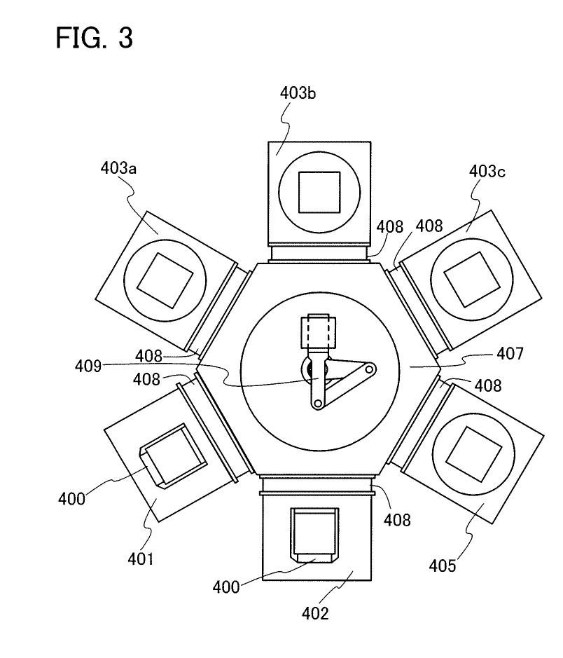

Note that it is preferable that the first impurity semiconductor layer 112p, the non-single-crystal semiconductor layer 114i, and the second impurity semiconductor layer 116n be doped with the small amount of an impurity for the purpose of controlling valence electron and be successively formed so that the interfaces with each layer are not exposed to the air. Therefore, it is desirable to employ a multi-chamber structure provided with a plurality of film formation treatment chambers. For example, a CVD apparatus illustrated in FIG. 2 may have a multi-chamber structure as illustrated in FIG. 3.

The plasma CVD apparatus shown in FIG. 3 includes a load chamber 401, an unload chamber 402, a treatment chamber (1) 403a, a treatment chamber (2) 403b, a treatment chamber (3) 403c, and a spare chamber 405 around a common chamber 407. For example, a p-type semiconductor layer (in this embodiment, the first impurity semiconductor layer 112p) is formed in the treatment chamber (1) 403a, an i-type semiconductor layer (in this embodiment, the non-single-crystal semiconductor layer 114i) is formed in the treatment chamber (2) 403b, and an n-type semiconductor layer (in this embodiment, the second impurity semiconductor layer 116n) is formed in the treatment chamber (3) 403c. In the plasma CVD apparatus illustrated in FIG. 3, a treatment chamber (the treatment chamber 141 shown in FIG. 2) in which the oxygen concentration and the carbon concentration in the treatment chamber are made as low as possible is used for at least the treatment chamber (2) 403b in which the non-single-crystal semiconductor layer 114i is formed. Of course, it is preferable that the oxygen concentration and the carbon concentration be made as low as possible in the whole plasma CVD apparatus including chambers (a load chamber, an unload chamber, treatment chambers, and a spare chamber).

An object is transferred to and from each chamber through the common chamber 407. A gate valve 408 is provided between the common chamber 407 and each of the rest of the chambers so that treatment carried out in different chambers may not interferer with each other. The object (the substrate) is placed in a cassette 400 provided in the load chamber 401 and transferred to each treatment chamber by a transfer unit 409 of the common chamber 407. After desired treatment is terminated, the object is placed in the cassette 400 provided in the unload chamber 402. In the apparatus with the multi-chamber structure as illustrated in FIG. 3, a treatment chamber can be provided for each kind of films to be formed, and a plurality of different kinds of films can be formed in succession without being exposed to the air.

An example of the formation of the first impurity semiconductor layer 112p, the non-single-crystal semiconductor layer 114i, and the second impurity semiconductor layer 116n is described with reference to FIG. 3.

The substrate 101 provided with the first electrode 102 is placed as an object in the cassette 400 of the load chamber 401. By the transfer unit 409 of the common chamber 407, the object is transferred to the treatment chamber (1) 403a. The first impurity semiconductor layer 112p is formed over the first electrode 102 of the object. Here, a p-type microcrystalline silicon layer is formed as the first impurity semiconductor layer 112p.

By the transfer unit 409 of the common chamber 407, the object is transferred from the treatment chamber (1) 403a to the treatment chamber (2) 403b. The non-single-crystal semiconductor layer 114i is formed over the first impurity semiconductor layer 112p of the object. The treatment chamber (2) 403b is, for example, an ultra-high treatment chamber in which the oxygen concentration and the carbon concentration are made as low as possible.

A reaction gas to be used for formation of the non-single-crystal semiconductor layer 114i is introduced into the treatment chamber (2) 403b to form a film. As the reaction gas to be used for formation of the non-single-crystal semiconductor layer 114i, a semiconductor source gas, a dilution gas, and a gas including nitrogen (typically, ammonia, chloroamine, fluoroamine, nitrogen, or the like) are used. The oxygen concentration and the carbon concentration of the reaction gas are made as low as possible. Also, a reaction gas including a nitrogen element and a hydrogen element, or a reaction gas including an NH group may be used.

Here, an example of the formation of the non-single-crystal semiconductor layer 114i is given. Silane (SiH₄) with a flow rate of 280 seem, hydrogen (H₂) with a flow rate of 300 sccm, and ammonia (NH₃) with a flow rate of 20 sccm are introduced into the treatment chamber (2) 403b and stabilized. The pressure in the treatment chamber (2) 403b is set to 170 Pa, and the temperature of the object is set to 280° C. Plasma discharge is performed under the condition where the RF power source frequency is 13.56 MHz and the power of the RF power source is 60 W, whereby a non-single-crystal silicon layer is formed. Thus, the non-single-crystal semiconductor layer 114i in which the nitrogen concentration is within a predetermined range and the concentrations of oxygen and carbon which are contained as impurities are made as low as possible can be formed. The flow rate and the concentration of a gas including nitrogen (in the above-described example, ammonia) to be introduced into the treatment chamber (2) 403b are controlled so that the concentration of nitrogen contained in the non-single-crystal semiconductor layer 114i is 5×10¹⁸/cm³ or more and 5×10²⁰/cm³ or less, preferably 1×10¹⁹/cm³ or more and 5×10²⁰/cm³ or less. Further, the environment in the treatment chamber (2) 403b and the purity of the gas to be introduced into the treatment chamber (2) 403b are controlled so that the concentrations of oxygen and carbon which are contained in the non-single-crystal semiconductor layer 114i are less than 5×10¹⁸/cm³, preferably less than 1×10¹⁸/cm³.

By introducing ammonia into the treatment chamber (2) 403b, the ammonia is dissociated by plasma discharge, so that an NH group is generated. The NH group is i into the non-single-crystal semiconductor layer 114i. In the case of introducing nitrogen, hydrogen included in the semiconductor source gas, the dilution gas, or the like reacts with nitrogen by plasma discharge, so that an NH group is generated. The NH group is introduced into the non-single-crystal semiconductor layer 114i.

By the transfer unit 409 of the common chamber 407, the object is transferred from the treatment chamber (2) 403b and the object is transferred to the treatment chamber (3) 403c, and the second impurity semiconductor layer 116n is formed over the non-single-crystal semiconductor layer 114i of the object. Here, as the second impurity semiconductor layer 116n, an n-type microcrystalline silicon layer is formed.

By the transfer unit 409 of the common chamber 407, the object is transferred from the treatment chamber (3) 403c and placed in the cassette 400 in the unload chamber 402.

In the above-described manner, the first impurity semiconductor layer 112p, the non-single-crystal semiconductor layer 114i, and the second impurity semiconductor layer 116n are formed, so that the unit cell 110 can be formed.

Note that as each of the impurity semiconductor layers (the first impurity semiconductor layer 112p and the second impurity semiconductor layer 116n) to be joined to the non-single-crystal semiconductor layer 114i, a semiconductor layer in which the nitrogen concentration is within a predetermined range and the oxygen concentration and the carbon concentration are low (for example, a semiconductor layer in which the nitrogen concentration is 5×10¹⁸/cm³ or more and 5×10²⁰/cm³ or less, preferably 1×10¹⁹/cm³ or more and 5×10²⁰/cm³ or less, and the oxygen concentration and the carbon concentration are less than 5×10¹⁸/cm³, preferably less than 1×10¹⁸/cm³) may be formed.

The second electrode 140 is formed over the second impurity semiconductor layer 116n.

As the second electrode 140, a reflective electrode is formed using aluminum, silver, titanium, tantalum, copper, or the like by a sputtering method or the like. Note that it is preferable to form unevenness at the interface between the second electrode 140 and the second impurity semiconductor layer 116n because the amount of light reflected is increased.

Thus, the photoelectric conversion device 100 illustrated in FIG. 1 can be manufactured.

In the non-single-crystal semiconductor layer 114i included in a main portion of a photoelectric conversion layer, the nitrogen concentration is within a predetermined range, and the concentrations of oxygen and carbon which are contained as impurities are made as low as possible. In specific, in the non-single-crystal semiconductor layer, the nitrogen concentration is 5×10¹⁸/cm³ or more and 5×10²⁰/cm³ or less, preferably 1×10¹⁹/cm³ or more and 5×10²⁰/cm³ or less, and the oxygen concentration and the carbon concentration are less than 5×10¹⁸/cm³, preferably less than 1×10¹⁸/cm³. By controlling the concentrations of nitrogen, oxygen, and carbon, defects in a non-single-crystal semiconductor layer can be reduced, whereby photoelectric conversion efficiency can be improved.

Impurities such as oxygen and carbon may lead to low photoelectric conversion efficiency. Therefore, the oxygen concentration and the carbon concentration in the non-single-crystal semiconductor layer are preferably made as low as possible. Meanwhile, as for nitrogen, it has been conventionally thought that the nitrogen concentration be preferably made as low as possible because nitrogen has been supposed to be a factor of low photoelectric conversion efficiency as with oxygen and carbon. It is also said that nitrogen forms a donor level in an i layer and thus nitrogen is supposed to be a factor of low photoelectric conversion efficiency as with oxygen. However, in one embodiment of the present invention, the nitrogen concentration falls within a predetermined range, whereby defects of a non-single-crystal semiconductor layer are reduced to improve photoelectric conversion efficiency. Hereinafter, an example of a model in which, by containing nitrogen in a non-single-crystal semiconductor layer, defects in a film is reduced to improve photoelectric conversion efficiency is described.

In a crystal structure of silicon, which is a typical semiconductor applied to one embodiment of the present invention, a network is formed in which silicon atoms are bonded to each other in a four-coordinate structure. Non-single-crystal silicon has a number of defects such as dangling bonds; therefore, in the case of using non-single-crystal silicon, the defects interrupt and break the network in which silicon atoms are bonded to each other.

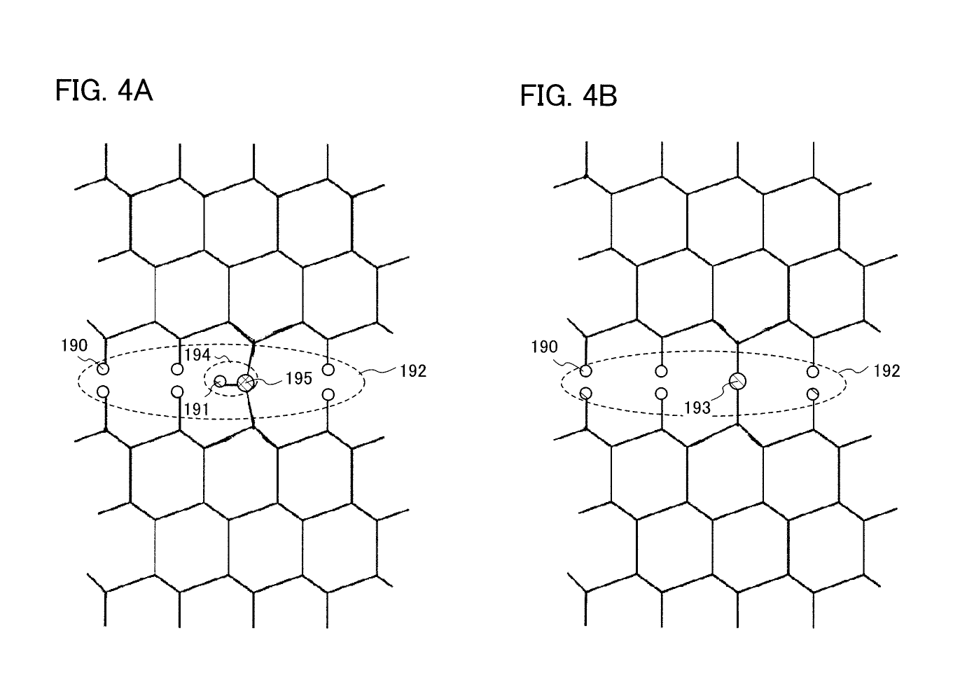

FIGS. 4A and 4B each schematically illustrate a network in which silicon atoms are bonded to each other in a non-single-crystal silicon layer. The illustrated network has a defect 192. In the defect 192, all dangling bonds of silicon atoms except one pair of dangling bonds are terminated with hydrogen atoms 190. Note that in FIGS. 4A and 4B, intersection points of lines denote silicon atoms, and lines denote bonds of silicon atoms and a network.

FIG. 4A illustrates a model (hereinafter, referred to as Model 1) in which the pair of dangling bonds is cross-linked with an NH group 194 and a network of silicon atoms is formed via the NH group 194. The NH group 194 includes a nitrogen atom 195 and a hydrogen atom 191.

FIG. 4B illustrates a model (hereinafter, referred to as Model 2) in which the pair of dangling bonds is cross-linked with an oxygen atom 193 so that a network of silicon atoms is formed via the oxygen atom 193.

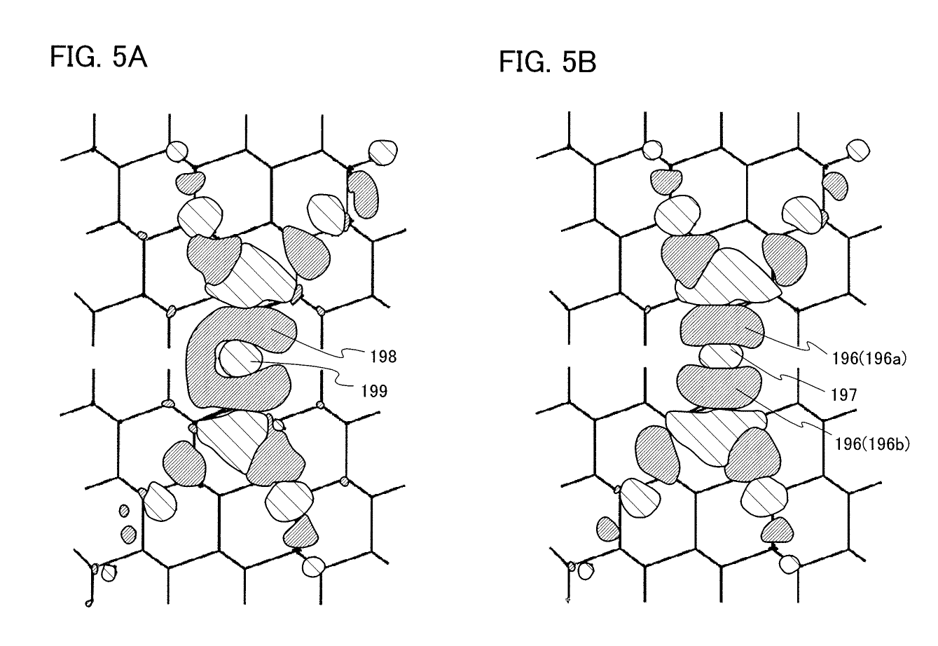

The lowest unoccupied molecular orbital (LUMO) of electrons is calculated (simulated) with respect to Model 1 and Model 2. FIG. 5A illustrates a result of the calculation with respect to Model 1. FIG. 5B illustrates a result of the calculation with respect to Model 2. As software for the calculation, first-principle calculation software using a density functional theory is used. Further, in order to evaluate effectiveness of an NH group and an oxygen atom, all dangling bonds except dangling bonds which are cross-linked with an NH group or an oxygen atom are terminated with hydrogen atoms.

FIG. 5A illustrates the shape of a wave function of a region in which cross-linking with an NH group is conducted in a network of silicon atoms and the periphery of the region. A region 198 and a region 199 have the same absolute value. Note that the region 198 is in opposite phase (positive phase or negative phase) to the region 199.

Similarly, FIG. 5B illustrates the shape of a wave function of a region in which cross-linking with an oxygen group is conducted in a network of silicon atoms and the periphery of the region. Regions 196 and a region 197 have the same absolute value. Note that the regions 196 are in opposite phase to the region 197 (the regions 196 are in positive phase when the region 197 is in negative phase, or the regions 196 are in negative phase when the region 197 is in positive phase).

FIG. 5A shows that in the case where the dangling bonds in the network are cross-linked with the NH group, the region 198 which is continuous and has the same phase and the same absolute value of a wave function is formed between the cross-linked silicon atoms. On the other hand, FIG. 5B shows that in the case where the dangling bonds in the network are cross-linked with the oxygen atom, as regions 196a and 196b in FIG. 5B, a region having the same phase and the same absolute value of a wave function are separated between the cross-linked silicon atoms. FIGS. 5A and 5B show that, in the case of cross-linking with the NH group, carrier flow is facilitated by a continuous region having the same phase and the same absolute value of a wave function, and in the case of cross-linking with the oxygen atom, carrier movement is hindered because regions having the same phase and the same absolute value of a wave function are separated from each other. That is, by containing an NH group in a non-single-crystal silicon layer, a bond which enables carrier movement can be formed in a defect which breaks the network. As a result, the flow of photogenerated carriers is facilitated and thus photoelectric conversion efficiency can be improved.

From the above, by containing an NH group in a non-single-crystal semiconductor layer, a bond which enables carriers to pass through can be formed in a defect such as a dangling bond, and thus, photoelectric conversion efficiency can be improved. Further, by reduction of oxygen atoms contained in a non-single-crystal semiconductor layer, a bond hindering carrier movement can be prevented from being formed in a defect.

An NH group can be contained in a non-single-crystal semiconductor layer using a gas including a nitrogen element and a hydrogen element or a gas including an NH group. In a non-single-crystal semiconductor layer, the oxygen concentration and the carbon concentration are low and the nitrogen concentration is within a predetermined concentration range, and in addition, an NH group is included, whereby the number of defects can be reduced and carriers can be made to flow efficiently. Therefore, by using such a non-single-crystal semiconductor layer for a photoelectric conversion layer, photoelectric conversion efficiency can be improved.

Note that the structure described in this embodiment can be implemented by being combined as appropriate with structures described in other embodiments in this specification.

### Embodiment 2

In this embodiment, a photoelectric conversion device having a structure different from the structure described in the above embodiment is described. In specific, an example in which an amorphous semiconductor layer is formed between the first impurity semiconductor layer 112p and the non-single-crystal semiconductor layer 114i is described.

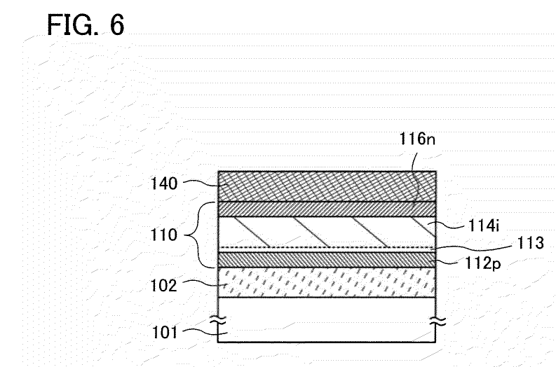

In the photoelectric conversion device illustrated in FIG. 6, the first electrode 102, the first impurity semiconductor layer 112p, an amorphous semiconductor layer 113, the non-single-crystal semiconductor layer 114i, the second impurity semiconductor layer 116n, and the second electrode 140 are stacked in this order from the first substrate 101 side. In this embodiment, the amorphous semiconductor layer 113 is provided between the first impurity semiconductor layer 112p and the non-single-crystal semiconductor layer 114i.

By providing the amorphous semiconductor layer 113 between the first impurity semiconductor layer 112p and the non-single-crystal semiconductor layer 114i, the non-single-crystal semiconductor layer 114i can be prevented from being affected by crystallinity of the first impurity semiconductor layer 112p. For example, in the case where the first impurity semiconductor layer 112p is formed using a microcrystalline semiconductor, the microcrystalline semiconductor may serve as a seed crystal, so that a needle-like crystal is included in the non-single-crystal semiconductor layer 114i. That is, the film quality of the non-single-crystal semiconductor layer 114i may be affected by the lower layer of the first impurity semiconductor layer 112p. Therefore, by providing the amorphous semiconductor layer 113 between the first impurity semiconductor layer 112p and the non-single-crystal semiconductor layer 114i, the formation of the non-single-crystal semiconductor layer 114i can be prevented from being affected by crystallinity of other layers or the like, whereby a film can be desirably formed.

As the amorphous semiconductor layer 113, a thin film with a thickness of about several nanometers may be formed. Further, as the amorphous semiconductor layer 113, an intrinsic or a substantially intrinsic semiconductor layer may be formed, and typically, an amorphous silicon layer is formed.

Note that the structure except the amorphous semiconductor layer 113 is obtained according to Embodiment 1; therefore, the description is omitted.

Note that the structure described in this embodiment can be implemented by being combined as appropriate with structures described in other embodiments in this specification.

### Embodiment 3

In this embodiment, a photoelectric conversion device having a structure different from the structures described in the above embodiments is described. In specific, an example in which the number of unit cells to be stacked is different from that in the photoelectric conversion device illustrated in FIG. 1 is described.

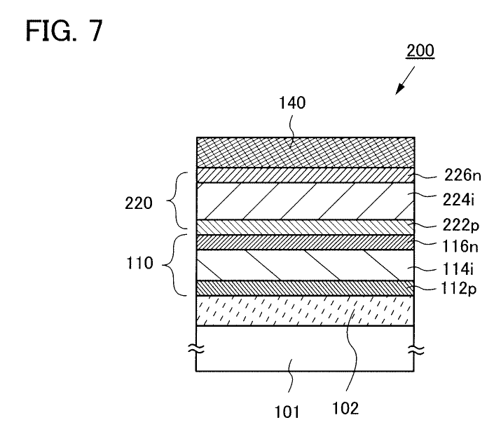

FIG. 7 is a tandem photoelectric conversion device 200 in which two unit cells are stacked. The photoelectric conversion device 200 includes the unit cell 110 formed over the substrate 101 provided with the first electrode 102, a unit cell 220 formed over the unit cell 110, and a second electrode 140 formed over the unit cell 220.

The unit cell 110 has a structure in which the first impurity semiconductor layer 112p, the non-single-crystal semiconductor layer 114i, and the second impurity semiconductor layer 116n are stacked in this order from the first electrode 102 side. The non-single-crystal semiconductor layer 114i included in the unit cell 110 is a semiconductor layer in which the nitrogen concentration is within a predetermined range and the oxygen concentration and the carbon concentration are made as low as possible. In specific, the nitrogen concentration of the non-single-crystal semiconductor layer 114i is set to 5×10¹⁸/cm³ or more and 5×10²⁰/cm³ or less, preferably 1×10¹⁹/cm³ or more and 5×10²⁰/cm³ or less, and the oxygen concentration and the carbon concentration thereof are each set to less than 5×10¹⁸/cm³, preferably less than 1×10¹⁸/cm³.

The unit cell 220 has a structure in which a third impurity semiconductor layer 222p, a non-single-crystal semiconductor layer 224i, and a fourth impurity semiconductor layer 226n are stacked in this order from the unit cell 110 side. The unit cell 220 includes at least one semiconductor junction.

In the photoelectric conversion device 200 shown in FIG. 7, in the case where light is incident from the substrate 101 side, it is preferable to provide a unit cell 110 including the non-single-crystal semiconductor layer to which one embodiment of the present invention is applied, as a unit cell on the light incidence side. Since a unit cell on the light incidence side is susceptible to degradation, it is preferable to provide a unit cell including a non-single-crystal semiconductor layer in which defects are reduced, as the unit cell on the light incidence side.

The non-single-crystal semiconductor layer 224i of the unit cell 220 is formed using an amorphous semiconductor (for example, amorphous silicon, amorphous silicon germanium, or the like) or a microcrystalline semiconductor (for example, microcrystalline silicon or the like). Further, as the non-single-crystal semiconductor layer 224i, a semiconductor layer in which the nitrogen concentration is within a predetermined range and the oxygen concentration and the carbon concentration are made as low as possible may be formed, like the non-single-crystal semiconductor layer 114i of the unit cell 110.

The third impurity semiconductor layer 222p and the fourth impurity semiconductor layer 226n are formed using an amorphous semiconductor (typically, amorphous silicon, amorphous silicon carbide, or the like) or a microcrystalline semiconductor (typically, microcrystalline silicon). Further, either the third impurity semiconductor layer 222p or the fourth impurity semiconductor layer 226n is a p-type semiconductor layer, and the other is an n-type semiconductor layer. Furthermore, as the third impurity semiconductor layer 222p, an impurity semiconductor layer having a conductivity type opposite to that of the second impurity semiconductor layer 116n of the unit cell 110 is formed. As the fourth impurity semiconductor layer 226n, an impurity semiconductor layer having a conductivity type opposite to that of the third impurity semiconductor layer 222p is formed. For example, a p-type semiconductor layer is formed as the third impurity semiconductor layer 222p, and an n-type semiconductor layer is formed as the fourth impurity semiconductor layer 226n.

Note that another unit cell may be further stacked, so that a stack type photoelectric conversion device or the like may be formed.

Further, an intermediate layer may be formed between stacked unit cells. The intermediate layer can be formed using a light-transmitting conductive material such as indium oxide, indium tin oxide alloy, zinc oxide, titanium oxide, magnesium zinc oxide, cadmium zinc oxide, cadmium oxide, an oxide semiconductor InGaO₃ZnO₅, an In—Ga—Zn—O based amorphous oxide semiconductor, and the like can be given.

Note that the structure described in this embodiment can be implemented by being combined as appropriate with structures described in other embodiments in this specification.

### Embodiment 4

In this embodiment, an example of an integrated photoelectric conversion device (a photoelectric conversion device module) is described in which a plurality of photoelectric conversion cells is formed over one substrate and the plurality of photoelectric conversion cells is connected in series, whereby a photoelectric conversion device is integrated. Further, in this embodiment, an example of the integration of a tandem photoelectric conversion device in which two unit cells are stacked in a longitudinal direction is described. Note that a photoelectric conversion device having one unit cell as shown in FIG. 1 may be integrated or a photoelectric conversion device in which three or more unit cells are stacked may be integrated. At least one unit cell includes a non-single-crystal semiconductor layer to which one embodiment of the present invention is applied. Hereinafter, a process for manufacturing an integrated photoelectric conversion device and the structure of the integrated photoelectric conversion device are briefly described.

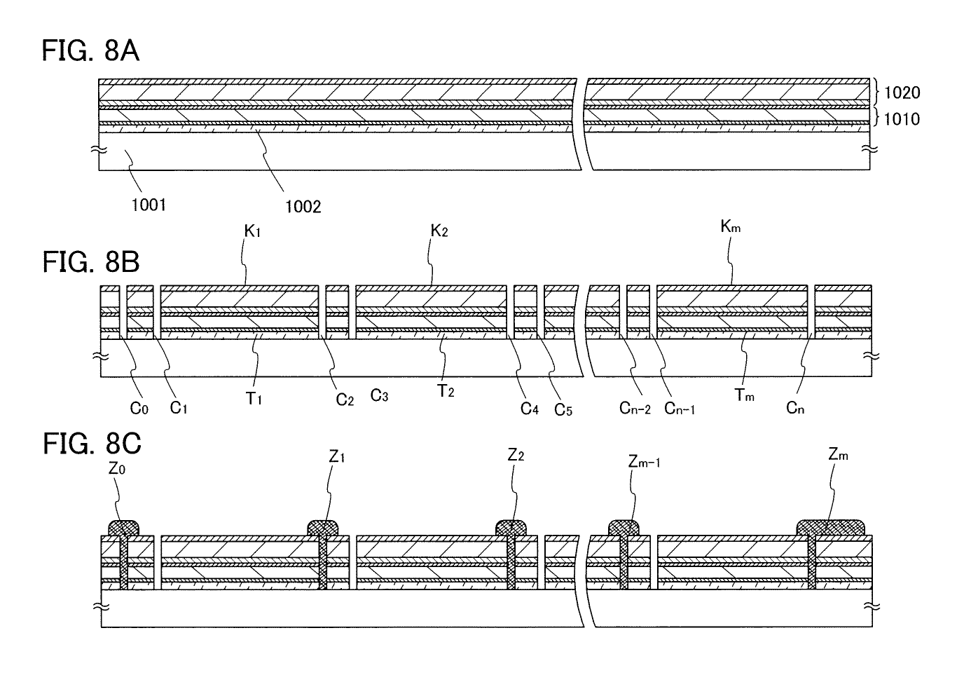

In FIG. 8A, a first electrode layer 1002 is provided over a substrate 1001. Alternatively, the substrate 1001 provided with the first electrode layer 1002 is prepared. The first electrode layer 1002 is formed using a light-transmitting conductive material such as indium oxide, indium tin oxide alloy, zinc oxide, tin oxide, or an alloy of indium oxide and zinc oxide to a thickness of 40 nm to 200 nm (preferably 50 nm to 100 nm) by a sputtering method, an evaporation method, a printing method, or the like. The sheet resistance of the first electrode layer 1002 may be approximately 20 Ω/square to 200 Ω/square.

Alternatively, the first electrode layer 1002 can be formed using a conductive composition including a light-transmitting conductive high molecular material. As a conductive high molecule included in a conductive composition, a so-called it electron conjugated conductive high molecule can be used. For example, polyaniline and/or a derivative thereof, polypyrrole and/or a derivative thereof, polythiophene and/or a derivative thereof, and a copolymer of two or more kinds of those materials can be given. In the case where a thin film is formed using a conductive composition as the first electrode layer 1002, it is preferable that the sheet resistance in the thin film formed using a conductive composition be 10000 Ω/square or less, the light transmittance in the wavelength 550 nm be 70% or higher, and the resistivity of the conductive high molecule included in the conductive composition be 0.1 Ω·cm or less.

Note that the above-described conductive high molecule may be used as a conductive composition by itself to form the first electrode layer 1002, or an organic resin may be mixed to adjust properties of a conductive composition to form the first electrode layer 1002. Furthermore, in order to control the electrical conductivity of the conductive composition, the redox potential of a conjugated electron of the conjugated conductive high molecule included in the conductive composition may be changed by doping the conductive composition with an acceptor dopant or a donor dopant.

A conductive composition is dissolved in water or an organic solvent (e.g., an alcohol-based solvent, a ketone-based solvent, an ester-based solvent, a hydrocarbon-based solvent, an aromatic-based solvent) and a thin film which serves as the first electrode layer 1002 can be formed by a wet process. In specific, the first electrode layer 1002 can be formed using a conductive composition by a wet process such as an application method, a coating method, a droplet discharge method (also referred to as an ink-jet method), or a printing method. The solvent is dried by heat treatment, heat treatment under reduced pressure, or the like. In the case where the properties of the conductive composition are adjusted by adding an organic resin to the conductive composition, when the added organic resin is a thermosetting resin, heat treatment may be further performed after the solvent is dried. When the organic resin is a photo-curing resin, light irradiation treatment may be performed after the solvent is dried.

Further, the first electrode layer 1002 can be formed using a light-transmitting composite conductive material in which an organic compound and an inorganic compound are combined. Note that “composition” does not simply mean a state in which two materials are mixed, but means a state in which charges can be transported between two (or more than two) materials by mixing the plurality of materials.

In specific, the light-transmitting composite conductive material is preferably formed using a composite material including a hole-transporting organic compound and metal oxide exhibiting electron accepting property with respect to the hole-transporting organic compound. The light-transmitting composite conductive material can have a resistivity of 1×10⁶ Ω·cm or less by compositing a hole-transporting organic compound and a metal oxide which shows an electron accepting property with respect to the hole-transporting organic compound. The hole-transporting organic compound refers to a substance with hole mobility higher than electron mobility, preferably with hole mobility of 10⁻⁶ cm²/Vsec or more. In specific, as the organic compound, various compounds such as an aromatic amine compound, a carbazole derivative, aromatic hydrocarbon, and a high molecular compound (oligomer, dendrimer, polymer, or the like) can be used. As the metal oxide, transition metal oxide is preferable. Among the transition metal oxide, an oxide of a metal belonging to any of Groups 4 to 8 in the periodic table is preferably used. In specific, vanadium oxide, niobium oxide, tantalum oxide, chromium oxide, molybdenum oxide, tungsten oxide, manganese oxide, and rhenium oxide are preferable because their electron-accepting property is high. Above all, molybdenum oxide is particularly preferable because of stability in the air, a low moisture absorption property, and easiness to be treated.

In the method for manufacturing the first electrode layer 1002 with use of the light-transmitting composite conductive material, any process may be employed whether it is a dry process or a wet process. For example, by co-evaporation using the above-described organic compound and inorganic compound, the first electrode layer 1002 using a light-transmitting composite conductive material can be formed. Further, the first electrode layer 1002 can also be obtained in such a way that a solution containing the aforementioned organic compound and metal alkoxide is applied and baked. The aforementioned organic compound and metal alkoxide can be applied by an ink-jet method, a spin-coating method, or the like.

In the case of forming the first electrode layer 1002 using a light-transmitting composite conductive material, by selecting a kind of an organic compound included in the light-transmitting composite conductive material, the first electrode layer 1002 having no absorption peak can be formed in a wavelength region of from approximately 450 nm to 800 nm in an ultraviolet region through infrared region. Therefore, the first electrode layer 1002 can efficiently transmit light in an absorption wavelength region in a non-single-crystal semiconductor layer, and thus, light absorption rate in a photoelectric conversion layer can be improved.

Further, as the first electrode layer 1002, a thin film with a thickness of about 1 nm to 20 nm is formed using a metal material such as aluminum, silver, gold, titanium, tungsten, platinum, nickel, or molybdenum; or an alloy including any of these. Thus, desired transmissivity can be obtained, so that light can be incident from the first electrode layer 1002 side.

Over the first electrode layer 1002, a unit cell 1010 and the unit cell 1020 are stacked in this order. The photoelectric conversion layer included in each of the unit cells 1010 and 1020 is formed using a semiconductor layer manufactured by a plasma CVD method and includes a semiconductor junction typified by a p-i-n junction. Note that an i layer which forms a semiconductor junction of at least one unit cell is formed using a non-single-crystal semiconductor layer in which the nitrogen concentration is within a predetermined range and the oxygen concentration and the carbon concentration are made as low as possible (specifically, a non-single-crystal semiconductor layer in which the nitrogen concentration is 5×10¹⁸/cm³ or more and 5×10²⁰/cm³ or less, preferably 1×10¹⁹/cm³ or more and 5×10²⁰/cm³ or less, and the oxygen concentration and the carbon concentration are less than 5×10¹⁸/cm³, preferably less than 1×10¹⁸/cm³ is used; more preferably, the non-single-crystal semiconductor layer including an NH group is used). Here, the i layer of the photoelectric conversion layer included in the unit cell 1010 provided on the light incidence side is formed using s non-single-crystal semiconductor layer in which the nitrogen concentration is within a predetermined range and the oxygen concentration and the carbon concentration are kept as low as possible. For example, as the unit cell 1010, the unit cell 1010 in which the first impurity semiconductor layer 112p, the non-single-crystal semiconductor layer 114i, and the second impurity semiconductor layer 116n which are described in the above embodiment are stacked is used.

Next, a photoelectric conversion cell which is subjected to element isolation is formed, so that a photoelectric conversion cell is integrated. A method for integrating a photoelectric conversion cell and a method for conducting element isolation are not limited in particular. Here, an example in which photoelectric conversion cells are separated and adjacent photoelectric conversion cells are electrically connected in series is described.

As shown in FIG. 8B, in order to form a plurality of photoelectric conversion cells over one substrate, openings C₀ to Cₙ which penetrate through a stack including the unit cell 1010 and the unit cell 1020 and the first electrode layer 1002 are formed by a laser processing method. The openings C₀, C₂, C₄, . . . Cₙ₋₂, and Cₙ are openings for insulating and separating unit cells. The openings are provided to form a plurality of photoelectric conversion cells which are subjected to element isolation. Further, the openings C₁, C₃, C₅, . . . , and Cₙ₋₁ are provided to form connections between separated first electrodes and second electrodes to be formed later over the stack including the unit cell 1010 and the unit cell 1020. By formation of the openings C₀ to Cₙ, the first electrode layer 1002 is divided into first electrodes T₁ to Tₘ and the stack including the unit cell 1010 and the unit cell 1020 is divided into multijunction cells K₁ to Kₘ. The kind of lasers used in a laser processing method for forming the openings is not limited, but a Nd-YAG laser, an excimer laser, or the like is preferably used. In any case, by performing laser processing in a state where the first electrode layer 1002, the unit cell 1010, and the unit cell 1020 are stacked, the first electrode layer 1002 can be prevented from being separated from the substrate 1001 during processing.

As shown in FIG. 8C, insulating layers Z₀ to Zₘ with which the openings C₀, C₂, C₄, . . . Cₙ₋₂, and Cₙ are filled and which cover upper end portions of the openings C₀, C₂, C₄, . . . , Cₙ₋₂, and Cₙ are formed. The insulating layers Z₀ to Zₘ can be formed by a screen printing method using a resin material having an insulating property such as an acrylic resin, a phenol resin, an epoxy resin, or a polyimide resin. For example, insulating resin patterns are formed using a resin composition in which cyclohexane, isophorone, high resistance carbon black, aerosil, dispersant, a defoaming agent, and a leveling agent are mixed with a phenoxy resin by a screen printing method so that the openings C₀, C₂, C₄, . . . , Cₙ₋₂, and Cₙ are filled therewith. After the insulating resin patterns are formed, thermal hardening is performed in an oven at 160° C. for 20 minutes, whereby the insulating layers Z₀ to Zₘ can be formed.

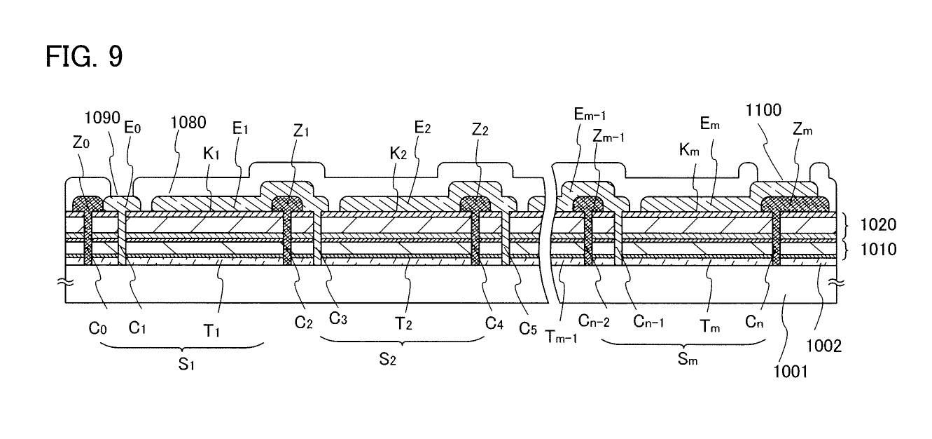

Next, second electrodes E₀ to Eₘ, illustrated in FIG. 9 are formed. The second electrodes E₀ to Eₘ are formed using a conductive material. The second electrodes E₀ to Eₘ may be formed by a sputtering method or a vacuum evaporation method using a conductive layer formed of aluminum, silver, molybdenum, titanium, chromium, or the like. Alternatively, the second electrodes E₀ to Eₘ can be formed using a conductive material which can be discharged. In the case where the second electrodes E₀ to Eₘ are formed using a conductive material which can be discharged, predetermined patterns are directly formed by a screen printing method, an ink-jet method, a dispenser method, or the like. For example, the second electrodes E₀ to Eₘ can be formed using a conductive material containing conductive particles of metal such as Ag, Au, Cu, W, or Al as its main component. In the case of manufacturing a photoelectric conversion device using a large-area substrate, the resistance of each of the second electrodes E₀ to Eₘ is preferably low. Therefore, a conductive material may be used in which particles of any of gold, silver, or copper which has low specific resistivity, preferably silver or copper which has low resistance are dissolved or dispersed as particles of metal in a solvent. Further, in order to sufficiently fill the openings C₁, C₃, C₅, which are subjected to laser processing with a conductive material, nanopaste with an average grain size of conductive particles of 5 nm to 10 nm is preferably used.

The second electrodes E₀ to Eₘ may be formed by discharging a conductive composition containing conductive particles in each of which a conductive material is covered with another conductive material. For example, as a conductive particle formed of Cu whose periphery is covered with Ag, a conductive particle provided with a buffer layer formed of nickel or nickel boron between Cu and Ag may be used. As the solvent, esters such as butyl acetate, alcohols such as isopropyl alcohol, or an organic solvent such as acetone is used. The surface tension and viscosity of the conductive composition which is discharged are appropriately adjusted by controlling concentration of a solution and adding a surface active agent or the like.

After the conductive composition which forms the second electrodes E₀ to Eₘ is discharged, a drying step and/or a baking step are/is performed under a normal pressure or a reduced pressure by laser beam irradiation, rapid thermal annealing (RTA), heating using a heating furnace, or the like. Both of the drying and baking steps are heat treatment, but for example, drying is performed at 100° C. for three minutes and baking is performed at 200° C. to 350° C. for 15 minutes to 120 minutes. Through this step, fusion and welding are accelerated by hardening and shrinking a peripheral resin, after the solvent in the conductive composition is volatilized or the dispersant in the conductive composition is chemically removed. The drying and baking are performed under an oxygen atmosphere, a nitrogen atmosphere, or an atmospheric atmosphere. However, it is preferable that the drying and baking be performed under an oxygen atmosphere in which a solvent in which conductive particles are dissolved or dispersed is easily removed.

The second electrodes E₀ to Eₘ come in contact with the unit cell 1020 which is the topmost layer of the multijunction cells K₁ to Kₘ. The contact between the second electrodes E₀ to Eₘ and the unit cell 1020 is ohmic contact, whereby low contact resistance can be obtained.

The second electrodes E₀ to Eₘ₋₁ are formed to be connected to the first electrodes T₁ to Tₘ respectively, in the openings C₁, C₃, C₅, . . . , Cₙ₋₁. That is, the openings C₁, C₃, C₅, . . . , Cₙ₋₁ are filled with the same material as the second electrodes E₀ to Eₘ₋₁. In such a manner, for example, the second electrode E₁ can be electrically connected to the first electrode T₂ and the second electrode Eₘ₋₁ can be electrically connected to the first electrode Tₘ. In other words, the second electrodes can be electrically connected to the first electrodes adjacent thereto, and each of the multijunction cells K₁ to Kₘ can obtain electrical connection in series.

Thus, over the substrate 1001, a photoelectric conversion cell S₁ including the first electrode T₁, the multijunction cell K₁, and the second electrode E₁, . . . , and a photoelectric conversion cell Sₘ including the first electrode Tm, the multijunction cell Kₘ, and the second electrode Eₘ are formed. The photoelectric conversion cells S₁ to Sₘ are electrically connected in series.

A sealing resin layer 1080 is formed so as to cover the photoelectric conversion cells S₁ to Sₘ. The sealing resin layer 1080 may be formed using an epoxy resin, an acrylic resin, or a silicone resin. Further, an opening 1090 is formed in the sealing resin layer 1080 over the second electrode E₀, and an opening 1100 is formed in the sealing resin layer 1080 over the second electrode Eₘ, so that connection with external wiring can be made in the opening 1090 and the opening 1100. The second electrode E₀ is connected to the first electrode T₁ and serves as one extraction electrode of the photoelectric conversion cells S₁ to Sₘ connected in series. The second electrode Eₘ serves as the other extraction electrode.

An integrated photoelectric conversion device can be manufactured using a photoelectric conversion cell having a non-single-crystal semiconductor layer to which one embodiment of the present invention is applied. By employing an integrated photoelectric conversion device, desired power (current, voltage) can be obtained.

Note that the structure described in this embodiment can be implemented by being combined as appropriate with structures described in other embodiments in this specification.

### Embodiment 5

In this embodiment, an example of the formation of a semiconductor layer in which the nitrogen concentration is within a predetermined range and the concentrations of oxygen and carbon which are contained as impurities are as low as possible is described. The semiconductor layer is formed as an impurity semiconductor layer which is joined in order to form an internal field effect or a semiconductor junction. Hereinafter, this embodiment is described with reference to the schematic view of the photoelectric conversion device 100 illustrated in FIG. 1.

The first electrode 102 is provided over the substrate 101, and the first impurity semiconductor layer 112p, the non-single-crystal semiconductor layer 114i, and the second impurity semiconductor layer 116n are provided in this order from the first electrode 102 side. In addition, the second electrode 140 is provided over the second impurity semiconductor layer 116n. At least one semiconductor junction (typically, a p-i-n junction) is formed using the first impurity semiconductor layer 112p, the non-single-crystal semiconductor layer 114i, and the second impurity semiconductor layer 116n.

In this embodiment, as one of or both the first impurity semiconductor layer 112p and the second impurity semiconductor layer 116n, a semiconductor layer in which the nitrogen concentration is within a predetermined range and the oxygen concentration and the carbon concentration are low (for example, a semiconductor layer in which the nitrogen concentration is 5×10¹⁸/cm³ or more and 5×10²⁰/cm³ or less, preferably 1×10¹⁹/cm³ or more and 5×10²⁰/cm³ or less, and the oxygen concentration and the carbon concentration are less than 5×10¹⁸/cm³, preferably less than 1×10¹⁸/cm³) is formed. Note that the first impurity semiconductor layer 112p and the second impurity semiconductor layer 116n are semiconductor layers each including an impurity element of one conductivity type.

A means similar to that in Embodiment 1 can be applied to a means for forming an impurity semiconductor layer of one conductivity type in which the nitrogen concentration is within a predetermined range and the oxygen concentration and the carbon concentration are low. In specific, the following means can be given: (1) the oxygen concentration and the carbon concentration of a reaction gas to be introduced into a treatment chamber are made low and the nitrogen concentration is made high, so that an impurity semiconductor layer of one conductivity type is formed; (2) the inner wall of a treatment chamber to be used for formation of an impurity semiconductor layer of one conductivity type is covered with a layer containing nitrogen at high concentration; (3) after an impurity semiconductor layer of one conductivity type is formed under the condition where the oxygen concentration and the carbon concentration of a reaction gas to be introduced into a treatment chamber are kept low, nitrogen is added to the impurity semiconductor layer of one conductivity type; and the like. In order to obtain the nitrogen concentration within a predetermined concentration range in the above means (1) to (3), a gas including nitrogen such as ammonia, chloroamine, fluoroamine, or a gas including nitrogen is preferably used. Further, any one of the above means (1) to (3) may be selected or a plurality of means may be combined.

In this embodiment, an impurity semiconductor layer of one conductivity type in which the nitrogen concentration is within a predetermined range and the oxygen concentration and the carbon concentration are low is formed. Therefore, when a semiconductor layer is formed by any of the above means (1) to (3), a doping gas including an impurity imparting one conductivity type is mixed into a reaction gas.

In an impurity semiconductor layer which is joined in order to form an internal field effect or a semiconductor junction, the nitrogen concentration falls within a predetermined concentration range and the concentrations of oxygen and carbon which are contained as impurities are made as low as possible. By controlling the concentrations of nitrogen, oxygen, and carbon, defects in an impurity semiconductor layer of one conductivity type can be reduced, whereby photoelectric conversion efficiency can be improved.

Note that it is preferable that the non-single-crystal semiconductor layer of this embodiment have an NH group or an NH₂ group.

Further, as in Embodiment 1, it is preferable that the non-single-crystal semiconductor layer 114i be also formed using a semiconductor layer in which the nitrogen concentration is within a predetermined range and the concentrations of oxygen and carbon which are contained as impurities are kept as low as possible.

In this embodiment, impurity semiconductor layers which are joined together in order to form an internal field effect or a semiconductor junction (the first impurity semiconductor layer 112p and the second impurity semiconductor layer 116n) are described. Of course, this embodiment is not limited to this, and it can be applied to an impurity semiconductor layer in the photoelectric conversion device shown in FIG. 6, the tandem photoelectric conversion device shown in FIG. 7, or a stack type photoelectric conversion device in which three or more unit cells are stacked.

Note that the structure of the semiconductor device described in this embodiment can be implemented by being combined as appropriate with structures described in other embodiments in this specification.

### Embodiment 6

In this embodiment, an impurity semiconductor layer which is joined in order to form an internal electric field or a semiconductor junction, particularly, a p-type semiconductor layer is described.

For example, the first impurity semiconductor layer 112p illustrated in FIG. 1 is formed using a p-type semiconductor layer. Further, in this embodiment, a p-type semiconductor layer containing carbon (typically, silicon carbide) is formed. By using a p-type semiconductor layer containing carbon, the bandgap of the p-type semiconductor layer which is joined in order to form an internal electric field or a semiconductor junction can be widened. Thus, open voltage of a photoelectric conversion device is increased, leading to improvement of photoelectric conversion efficiency.

The p-type semiconductor layer containing carbon can be formed by mixing a gas including carbon (for example, a methane (CH₄) gas) into a reaction gas (including a semiconductor source gas, a dilution gas, a doping gas, and the like) for forming a p-type semiconductor layer. Alternatively, the p-type semiconductor layer containing carbon may be formed by adding carbon after a p-type semiconductor layer is formed.

Note that in this embodiment a p-type semiconductor layer (the first impurity semiconductor layer 112p) which is joined in order to form an internal electric field or a semiconductor junction is described with reference to FIG. 1. Of course, this embodiment is not limited to this, and it can be applied to a p-type semiconductor layer in the photoelectric conversion device shown in FIG. 6, the tandem photoelectric conversion device shown in FIG. 7, or a stack type photoelectric conversion device in which three or more unit cells are stacked.

Note that the structure of the semiconductor device described in this embodiment can be implemented by being combined as appropriate with structures described in other embodiments in this specification.

### Embodiment 7

In this embodiment, an impurity semiconductor layer which is joined in order to form an internal electric field or a semiconductor junction, particularly, an n-type semiconductor layer, is described.

For example, the second impurity semiconductor layer 116n illustrated in FIG. 1 is formed using an n-type semiconductor layer. Further, in this embodiment, an n-type semiconductor layer containing nitrogen is formed. By using an n-type semiconductor layer containing nitrogen, the bandgap of the n-type semiconductor layer which is joined in order to form an internal electric field or a semiconductor junction can be widened. Thus, open voltage of a photoelectric conversion device becomes high, leading to improvement of photoelectric conversion efficiency.

The n-type semiconductor layer containing nitrogen can be formed by mixing a gas including nitrogen (for example, ammonia, chloroamine, fluoroamine, or the like) into a reaction gas (including a semiconductor source gas, a dilution gas, a doping gas, and the like) for forming an n-type semiconductor layer. Further, as the n-type semiconductor layer of this embodiment, an impurity semiconductor layer of one conductivity type in which the nitrogen concentration is within a predetermined range and the oxygen concentration and the carbon concentration are low, which is described in Embodiment 5, can be formed. Alternatively, the n-type semiconductor layer containing nitrogen may be formed by adding nitrogen after an n-type semiconductor layer is formed. The nitrogen concentration range of the n-type semiconductor layer is set so that semiconductivity is kept and the bandgap is widened.

Note that in this embodiment an n-type semiconductor layer (the second impurity semiconductor layer 116n) which is joined in order to form an internal electric field or a semiconductor junction is described with reference to FIG. 1. Of course, this embodiment is not limited to this, and it can be applied to an n-type semiconductor layer in the photoelectric conversion device illustrated in FIG. 6, the tandem photoelectric conversion device illustrated in FIG. 7, or a stack type photoelectric conversion device in which three or more unit cells are stacked. Further, the structure of a unit cell can include: a p-type semiconductor layer in which carbon is contained and the bandgap is widened (refer to Embodiment 6 and the like); an n-type semiconductor layer in which the nitrogen concentration is within a predetermined range and the bandgap is widened (refer to this embodiment and the like); and an i-type semiconductor layer in which the nitrogen concentration is within a predetermined range and the concentrations of oxygen and carbon which are contained as impurities are as low as possible, so that defects are reduced.

Note that the structure of the semiconductor device described in this embodiment can be implemented by being combined as appropriate with structures described in other embodiments in this specification.

### Embodiment 8

In the above embodiments, an example in which an NH group is contained in a non-single-crystal semiconductor layer is described. In this embodiment, an example in which an NH₂ group is contained in a non-single-crystal semiconductor layer is described. In addition, an example of a model of improving photoelectric conversion efficiency by containing an NH₂ group in a non-single-crystal semiconductor layer is described. In specific, a structure is provided in which, in a schematic view of the photoelectric conversion device illustrated in FIG. 1, an NH₂ group is contained in the non-single-crystal semiconductor layer 114i, whereby nitrogen is contained in the non-single-crystal semiconductor layer 114i.

Note that in the non-single-crystal semiconductor layer 114i, the peak concentration of nitrogen, which is measured by secondary ion mass spectrometry, is 5×10¹⁸/cm³ or more and 5×10²⁰/cm³ or less, preferably 1×10¹⁹/cm³ or more and 5×10²⁰/cm³ or less, and the peak concentrations of oxygen and carbon, which are measured by secondary ion mass spectrometry, are less than 5×10¹⁸/cm³, preferably less than 1×10¹⁸/cm³.

As described above, in a crystal structure of silicon, which is a typical semiconductor applied to one embodiment of the present invention, a network is formed in which silicon atoms are bonded to each other in a four-coordinate structure. In the case of using non-single-crystal silicon, it has a number of defects such as dangling bonds, leading to low photoelectric conversion efficiency.

In this embodiment, an effect of terminating dangling bonds in non-single-crystal silicon with an NH₂ group to improve photoelectric conversion efficiency by containing nitrogen in a non-single-crystal silicon layer, is described. Note that “terminating dangling bonds in non-single-crystal silicon with an NH₂ group” means that an NH₂ group is bonded to silicon atoms in a non-single-crystal silicon layer. A first bond and a second bond of a nitrogen atom are bonded to different hydrogen atoms, and a third bond of the nitrogen atom is bonded to a silicon atom.

In order to consider the mechanism of a model in which dangling bonds of a silicon atom were terminated with an NH₂ group, a defect level and bond energy were simulated using first principle calculation. As software for the simulation, CASTEP, software of first principle calculation, produced by Accelrys Software Inc. was used.

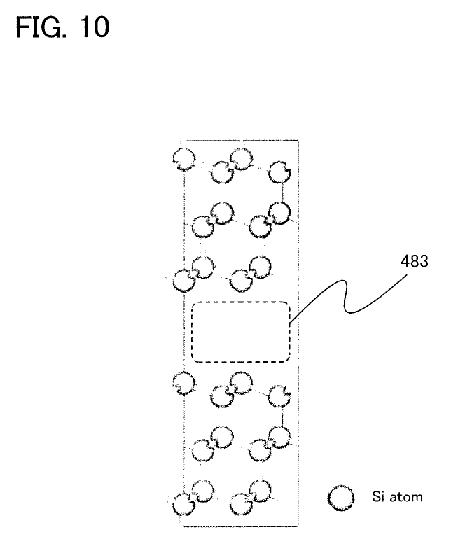

A defect level of bonding network of a silicon atom (a Si atom in FIG. 10) having a defect 483 as illustrated in FIG. 10 and repair thereof were calculated. Specifically, density of states of electrons was calculated with respect to a defect structure, an H-termination structure in which a defect was terminated with a hydrogen atom, and an NH₂-termination structure in which a defect was terminated with an NH₂ group. Note that the defect structure, the H-termination structure in which a defect was terminated with a hydrogen atom, and the NH₂-termination structure in which a defect was terminated with an NH₂ group were optimized in terms of atomic configuration, and the density of states for electrons of each structure was calculated. GGA (generalized gradient approximation)-PBE was used for a functional and an ultrasoft type was used for pseudopotential.

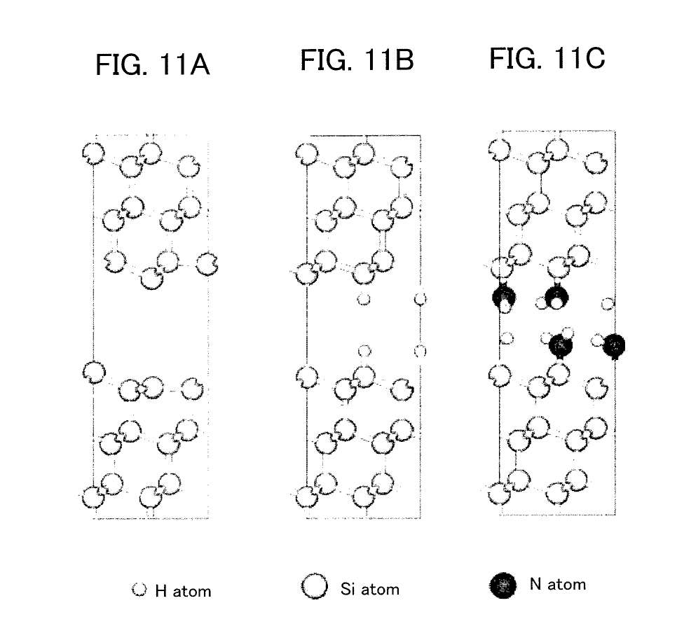

FIGS. 11A to 11C illustrate the defect structure, the H-termination structure in which a defect was terminated with a hydrogen atom, and the NH₂-termination structure in which a defect was terminated with an NH₂ group which were optimized in terms of atomic configuration. FIG. 11A illustrates the defect structure, FIG. 11B illustrates the H-termination structure, and FIG. 11C illustrates the NH₂-termination structure. In FIG. 11A, since there are dangling bonds, atomic positions around the defect change largely for a structure which is stable in energy.

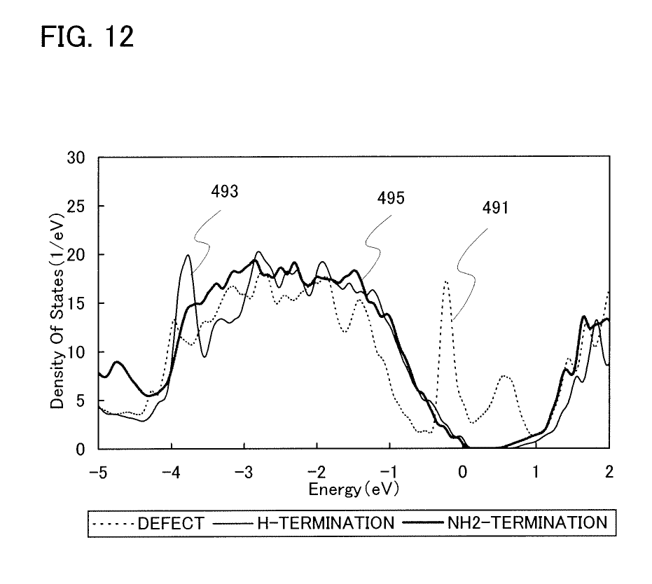

FIG. 12 shows the density of states of electrons. A dashed line 491 denotes the density of states of electrons in the defect structure. A narrow solid line 493 denotes the density of states of electrons in the H-termination structure, and a wide solid line 495 denotes the density of states of electrons in the NH₂-termination structure. An origin point on energy is Fermi energy of each structure.

As denoted by the dashed line 491 in FIG. 12, it is found that, in the defect structure, a defect level is formed in a band gap at energy of about −0.3 eV to 0.6 eV. In contrast, in the H-termination structure and the NH₂-termination structure, the defect levels disappear as denoted by the narrow solid line 493 and the wide solid line 495. Therefore, it can be said that defects are repaired. That is, in the NH₂-termination structure, since the defects are repaired, trap levels disappear due to the defects, so that it can be said that annihilation of photogenerated carriers due to recombination can be suppressed.

### (Bond Energy)

Next, bond energy is described. According to FIG. 12, it was found that the defect levels can be reduced in the NH₂-termination structure. However, it is necessary that the bond be strong so that the defect levels are stably reduced when a photoelectric conversion device converts light into electricity and the photoelectric conversion device is not deteriorated. Thus, Si—H bond energy in the H-termination structure, N—H bond energy in the NH₂-termination structure, and Si—NH₂ bond energy in the NH₂-termination structure were calculated and stability of the bonds in the structures were compared to each other.

Si—H bond energy in the H-termination structure illustrated in FIG. 11B can be calculated using an equation (1).

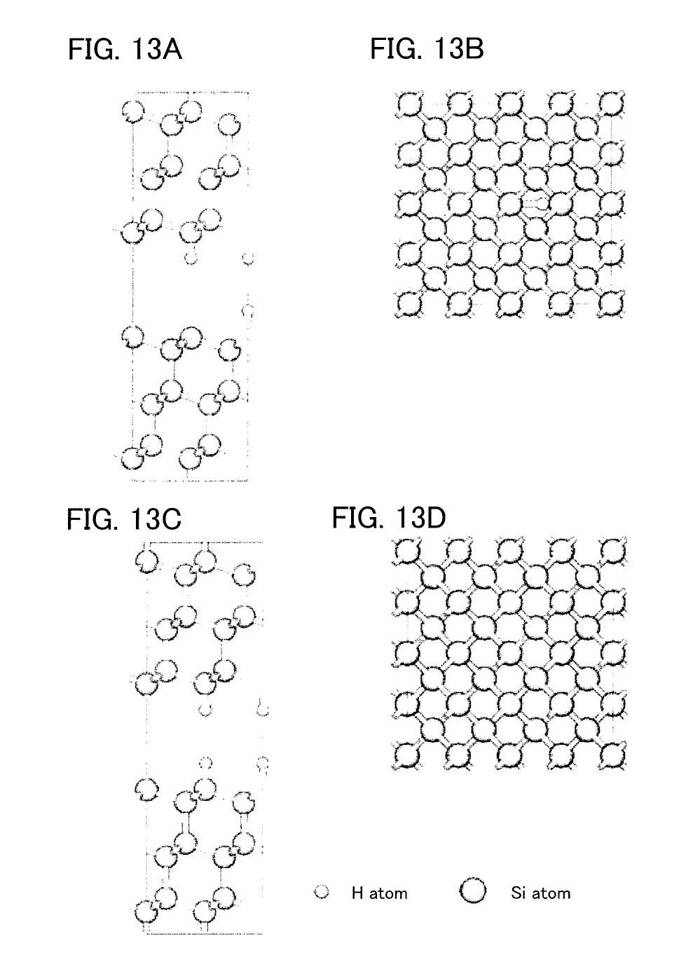

(Si—H bond energy in the H-termination structure)=(Energy in the optimized structure obtained by removing one hydrogen atom from the H-termination structure (FIG. 13A))+(Energy of Si:Hᵢₙₜ (FIG. 13B))−(Energy of the H-termination structure (FIG. 13C))−(Energy of Si crystal (FIG. 13D)) (1)

Si:Hᵢₙₜ indicates a state where an H atom exists between Si crystal lattices. In addition, the sum of Si atoms and H atoms in an initial state (FIG. 13A and FIG. 13B) corresponds to that in a final state (FIG. 13C and FIG. 13D).

As for N—H bond energy in the NH₂-termination structure, a structure in which H exists between lattices of a Si crystal is employed as a state of H which has been subjected to the cleavage of the N—H bond. Further, as for Si—NH₂ bond energy in the NH₂-termination structure, a structure in which NH₂ exists between lattices of a Si crystal is employed as a state of NH₂ which has been subjected to the cleavage of the Si—NH₂ bond.

N—H bond energy in the NH₂-termination structure illustrated in FIG. 11C can be calculated using an equation (2).

(N—H bond energy in the NH₂-termination structure)=(Energy in the optimized structure obtained by removing one H from the NH₂-termination structure)+(Energy of Si:Hᵢₙₜ)−(Energy of the NH₂-termination structure)−(Energy of Si crystal) (2)

Si—NH₂ bond energy in the NH₂-termination structure illustrated in FIG. 11C can be calculated using an equation (3).

(Si—NH₂ bond energy in the NH₂-termination structure)=(Energy in the optimized structure obtained by removing one NH₂ from the NH₂-termination structure)+(Energy of Si:NH₂)−(Energy of the NH₂ termination structure)−(Energy of Si crystal) (3)

Si:NH₂ indicates a state where an NH₂ group exists between Si crystal lattices.

Each structure of terms in the equations (1) to (3) was determined by structure optimization with respect to atomic configuration, and energy was calculated. In a similar manner to the above (defect level) simulation, GGA-PBE was used for a functional and an ultrasoft type was used for pseudopotential.

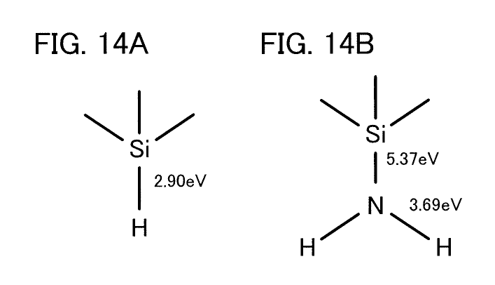

FIGS. 14A and 14B show the calculation results of bond energy along with schematic diagrams of the structures. FIG. 14A illustrates the H-termination structure in which a dangling bond of Si is terminated with H, and FIG. 14B illustrates the NH₂-termination structure in which a dangling bond of Si is terminated with NH₂. Si—H bond energy of the H-termination structure is 2.90 eV. Further, Si—N bond energy of the NH₂-termination structure is 5.37 eV and N—H bond energy is 3.69 eV. Two bond energies of the NH₂ group (Si—N bond energy and N—H bond energy) are larger than bond energy of Si—H in which a dangling bond of Si is terminated with H and the NH₂-termination structure can be said to be a stable structure. Therefore, it is found that when dangling bonds of a silicon layer are terminated with an NH₂ group, the NH₂ group bonded to Si and H bonded to N are not easily dissociated, and defects are not easily generated.

From the consideration of a defect level and bond energy, it is found that defect levels are reduced in the silicon layer by termination of dangling bonds of the silicon atom with the NH₂ group. Thus, annihilation of photogenerated carriers can be suppressed. Further, it is found that since the NH₂ group bonded to Si has a more stable structure than the H atom bonded to Si, a photoelectric conversion device having the silicon layer including an NH₂ group is not easily photodeteriorated. From the above, by containing an NH₂ group in a non-single-crystal silicon layer, annihilation of photogenerated carriers can be suppressed and thus photoelectric conversion efficiency can be improved.

Note that the structure described in this embodiment can be implemented by being combined as appropriate with structures described in other embodiments in this specification. Therefore, an NH₂ group can be contained in a non-single-crystal semiconductor layer of one embodiment of the present invention in which the nitrogen concentration, the carbon concentration, and the oxygen concentration are controlled which are described in other embodiments (Embodiments 1 to 7).

### Embodiment 9

In this embodiment, a film property of a non-single-crystal semiconductor layer according to one embodiment of the present invention is described. In specific, in this embodiment, the non-single-crystal silicon layer of one embodiment of the present invention which is different from a conventional amorphous silicon layer in film property is described, and further, the non-single-crystal silicon layer having a peak region of a spectrum obtained by measurement with low-temperature photoluminescence spectroscopy of 1.31 eV or more and 1.39 eV or less is described.

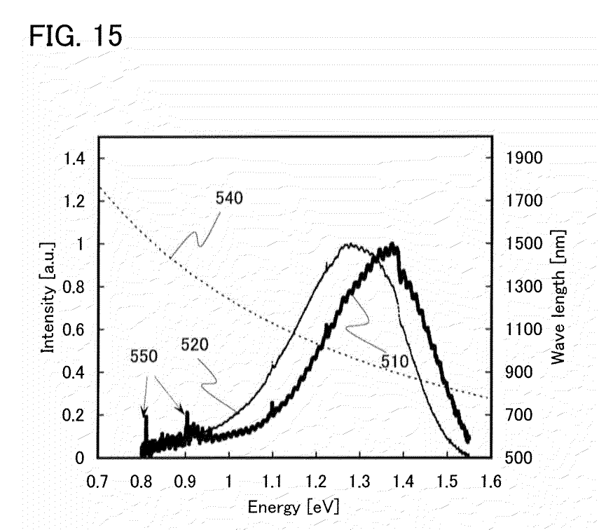

FIG. 15 illustrates a result obtained by performing an evaluation on the non-single-crystal silicon layer of one embodiment of the present invention with low-temperature photoluminescence (PL) spectroscopy.

In FIG. 15, a spectrum 510 indicated by a wide solid line was obtained by measuring the non-single-crystal silicon layer (Sample A) of one embodiment of the present invention with low-temperature photoluminescence spectroscopy. In addition, a spectrum 520 indicated by a narrow solid line was obtained by measuring the conventional amorphous silicon layer (Sample B: an amorphous silicon layer in which the nitrogen concentration is not controlled) with low-temperature photoluminescence spectroscopy. In FIG. 15, a Y axis in the left side indicates photoluminescence intensity. In addition, a dashed line 540 in FIG. 15 indicates values obtained by converting values of photon energy of the X axis into a measurement wavelength and corresponds to a Y axis in the right side.

Here, Sample A with the spectrum 510 measured is a non-single-crystal silicon layer which is formed by mixing ammonia (NH₃) into a reaction gas (silane (SiH₄) and hydrogen (H₂)) which are introduced into a treatment chamber.

On the other hand, Sample B with the spectrum 520 measured is an amorphous silicon layer which is formed without mixture of a gas including nitrogen such as ammonia into a reaction gas to be introduced into a treatment chamber.

Note that LabRAM HR-PL manufactured by Horiba Jobin Yvon was used for the measurement by photoluminescence spectroscopy. As excitation light, argon laser light with a wavelength of 514.5 nm was used. As a detector, an InGaAs photodiode with which an infrared region was able to be measured was used and the samples in measurement were cooled with liquid helium. In this time, a temperature was set to 4.2 K using MicrostatHe manufactured by Oxford Instruments plc. as a cooler. Note that the samples were set on a cooling plate provided with a thermocouple with use of grease and a temperature of the thermocouple was set to the aforementioned temperature.

The spectrum 510 is normalized based on the maximum intensity of the spectrum 510. Similarly, the spectrum 520 is normalized based on the maximum intensity of the spectrum 520. Further, the peak having a needle-like shape in each of the spectra (for example, a peak 550 in FIG. 15) is due to the influence of a fluorescent light under measurement environment.

Table 1 shows the peak region and a half-width of the spectrum 510 in Sample A and the peak region and a half-width of the spectrum 520 in Sample B. Note that each of the peak regions of the spectra corresponds to a region where a value of intensity is greater than or equal to 90%.

TABLE 1

| | peak region | half-widths (FWHM) |
|---|---|---|
| Sample A | 1.31 eV or more-1.39 eV or less | 0.261 eV |
| (spectrum 510) | | |
| Sample B | 1.23 eV or more-1.35 eV or less | 0.290 eV |
| (spectrum 520) | | |

When the peak regions of the spectra were compared to each other, the spectrum 510 of Sample A is shifted toward the higher energy side than the spectrum 520 of Sample B. Further, as for the half-widths of the spectra, the spectrum 510 of Sample A has the narrower half-width than the spectrum 520 of Sample B. This means that transition levels between a hole trapping center in a valence band tail and a conduction band tail by a radiation process are wide in Sample A. Accordingly, it shows that Sample A is structurally well-ordered compared with Sample B. Further, it is obvious from FIG. 15 and Table 1 that Sample A (the non-single-crystal silicon layer which is one embodiment of the present invention) is different in physical properties from Sample B (the conventional amorphous silicon layer).

The non-single-crystal semiconductor layer which is one embodiment of the present invention includes a non-single-crystal semiconductor layer which has a peak region of a spectrum obtained by measurement with low-temperature photoluminescence spectroscopy of 1.31 eV or more and 1.39 eV or less, which is different from the conventional non-single-crystal semiconductor layer.

Note that a structure in which the non-single-crystal semiconductor layer of this embodiment (specifically, a semiconductor layer having a peak region of a spectrum obtained by measurement with low-temperature photoluminescence spectroscopy of 1.31 eV or more and 1.39 eV or less) includes an NH group or an NH₂ group may be employed.

Note that the structure described in this embodiment can be implemented by being combined as appropriate with structures described in other embodiments in this specification. Therefore, the peak region of a spectrum obtained by low-temperature photoluminescence spectroscopy may be 1.31 eV or more and 1.39 eV or less also in a non-single-crystal semiconductor layer of one embodiment of the present invention in which the nitrogen concentration, the carbon concentration, and the oxygen concentration are controlled which are described in other embodiments (Embodiments 1 to 8).

This application is based on Japanese Patent Application serial no. 2008-248422 filed with Japan Patent Office on Sep. 26, 2008, the entire contents of which are hereby incorporated by reference.

1. A photoelectric conversion device comprising:
an unit cell between a first electrode and a second electrode, the unit cell comprising a first impurity semiconductor layer of one conductivity type, a non-single-crystal semiconductor layer, and a second impurity semiconductor layer of opposite conductivity type to the first impurity semiconductor layer which are sequentially stacked so as to form semiconductor junctions,
wherein the non-single-crystal semiconductor layer includes an NH group.

2. The photoelectric conversion device according to claim 1, wherein a concentration of nitrogen in the non-single-crystal semiconductor layer, which is measured by secondary ion mass spectrometry, is 5×10¹⁸/cm³ or more and 5×10²⁰/cm³ or less, and
wherein concentrations of oxygen and carbon in the non-single-crystal semiconductor layer, which are measured by secondary ion mass spectrometry, are less than 5×10¹⁸/cm³.

3. The photoelectric conversion device according to claim 2, wherein the concentration of nitrogen in the non-single-crystal semiconductor layer, which is measured by secondary ion mass spectrometry, is 1×10¹⁹/cm³ or more and 5×10²⁰/cm³ or less in the non-single-crystal semiconductor layer.

4. The photoelectric conversion device according to claim 1, further comprising an amorphous semiconductor layer between the first impurity semiconductor layer and the non-single-crystal semiconductor layer.

5. A photoelectric conversion device comprising:
an unit cell between a first electrode and a second electrode, the unit cell comprising a first impurity semiconductor layer of one conductivity type, a non-single-crystal semiconductor layer, and a second impurity semiconductor layer of opposite conductivity type to the first impurity semiconductor layer which are sequentially stacked so as to form semiconductor junctions,
wherein the non-single-crystal semiconductor layer includes an NH₂ group.

6. The photoelectric conversion device according to claim 5, wherein a concentration of nitrogen in the non-single-crystal semiconductor layer, which is measured by secondary ion mass spectrometry, is 5×10¹⁸/cm³ or more and 5×10²⁰/cm³ or less, and
wherein concentrations of oxygen and carbon in the non-single-crystal semiconductor layer, which are measured by secondary ion mass spectrometry, are less than 5×10¹⁸/cm³.

7. The photoelectric conversion device according to claim 6, wherein the concentration of nitrogen in the non-single-crystal semiconductor layer, which is measured by secondary ion mass spectrometry, is 1×10¹⁹/cm³ or more and 5×10²⁰/cm³ or less in the non-single-crystal semiconductor layer.

8. The photoelectric conversion device according to claim 5, further comprising an amorphous semiconductor layer between the first impurity semiconductor layer and the non-single-crystal semiconductor layer.

9. A photoelectric conversion device comprising:
a plurality of unit cells stacked between a first electrode and a second electrode, each unit cell comprising a first impurity semiconductor layer of one conductivity type, a non-single-crystal semiconductor layer, and a second impurity semiconductor layer of an opposite conductivity type to the first impurity semiconductor layer which are sequentially stacked so as to form semiconductor junctions,
wherein, in a light incident side unit cell, the non-single-crystal semiconductor layer includes an NH group.

10. The photoelectric conversion device according to claim 9, wherein, in at least the light incident side unit cell, a concentration of nitrogen in the non-single-crystal semiconductor layer, which is measured by secondary ion mass spectrometry, is 5×10¹⁸/cm³ or more and 5×10²⁰/cm³ or less, and
wherein, in at least the light incident side unit cell, concentrations of oxygen and carbon in the non-single-crystal semiconductor layer, which are measured by secondary ion mass spectrometry, are less than 5×10¹⁸/cm³.

11. The photoelectric conversion device according to claim 10, wherein, in at least the light incident side unit cell, the concentration of nitrogen in the non-single-crystal semiconductor layer, which is measured by secondary ion mass spectrometry, is 1×10¹⁹/cm³ or more and 5×10²⁰/cm³ or less in the non-single-crystal semiconductor layer.

12. The photoelectric conversion device according to claim 9, further comprising an amorphous semiconductor layer between the first impurity semiconductor layer and the non-single-crystal semiconductor layer in at least one of the unit cells.

13. A photoelectric conversion device comprising:
a plurality of unit cells stacked between a first electrode and a second electrode, each unit cell comprising a first impurity semiconductor layer of one conductivity type, a non-single-crystal semiconductor layer, and a second impurity semiconductor layer of an opposite conductivity type to the first impurity semiconductor layer which are sequentially stacked so as to form semiconductor junctions,
wherein, in a light incident side unit cell, the non-single-crystal semiconductor layer includes an NH₂ group.

14. The photoelectric conversion device according to claim 13, wherein, in at least the light incident side unit cell, a concentration of nitrogen in the non-single-crystal semiconductor layer, which is measured by secondary ion mass spectrometry, is 5×10¹⁸/cm³ or more and 5×10²⁰/cm³ or less, and
wherein, in at least the light incident side unit cell, concentrations of oxygen and carbon in the non-single-crystal semiconductor layer, which are measured by secondary ion mass spectrometry, are less than 5×10¹⁸/cm³.

15. The photoelectric conversion device according to claim 13, wherein, in at least the light incident side unit cell, the concentration of nitrogen in the non-single-crystal semiconductor layer, which is measured by secondary ion mass spectrometry, is 1×10¹⁹/cm³ or more and 5×10²⁰/cm³ or less in the non-single-crystal semiconductor layer.

16. The photoelectric conversion device according to claim 13, further comprising an amorphous semiconductor layer between the first impurity semiconductor layer and the non-single-crystal semiconductor layer in at least one of the unit cells.

17. A method for manufacturing a photoelectric conversion device comprising the steps of:
forming a first electrode over a substrate;
forming a first impurity semiconductor layer of one conductivity type over the first electrode;
forming a non-single-crystal semiconductor layer over the first impurity semiconductor layer;
forming a second impurity semiconductor layer of opposite conductivity type to the first impurity semiconductor layer over the non-single-crystal semiconductor layer; and
forming a second electrode over the second impurity semiconductor layer,
wherein the non-single-crystal semiconductor layer is formed by steps of:
subjecting a treatment chamber to vacuum exhaust to a degree of vacuum of 1×10⁻⁵ Pa or less;
introducing a semiconductor source gas, a dilution gas, and a gas including nitrogen into the treatment chamber; and
producing plasma in the treatment chamber.

18. The method for manufacturing a photoelectric conversion device according to claim 17, wherein in the non-single-crystal semiconductor layer, a concentration of nitrogen, which is measured by secondary ion mass spectrometry, of 5×10¹⁸/cm³ or more and 5×10²⁰/cm³ or less, and concentrations of oxygen and carbon, which are measured by secondary ion mass spectrometry, of less than 5×10¹⁸/cm³.

19. The method for manufacturing a photoelectric conversion device according to claim 17, wherein a gas including ammonia, chloroamine, or fluoroamine, or nitrogen is used as the gas including nitrogen.
